(19) United States
(12) Patent Application Publication
(10) Pub. No.: US 2024/0332459 A1
(43) Pub. Date: Oct. 3, 2024

(54) DISPLAY DEVICE AND REPAIR METHOD THEREOF

(71) Applicant: Samsung Display Co., LTD., Yongin-si (KR)

(72) Inventor: Byeong Kyun CHOI, Yongin-si (KR)

(21) Appl. No.: 18/615,709

(22) Filed: Mar. 25, 2024

(30) Foreign Application Priority Data
Mar. 31, 2023 (KR) 10-2023-0042654

(51) Int. Cl. H01L 33/38; G09G 3/00; H01L 25/075; H01L 25/16; H01L 33/62

(52) U.S. Cl. CPC H01L 33/387; G09G 3/006; H01L 25/0753; H01L 25/167; H01L 33/62; G09G 2330/08

(57) ABSTRACT

A display device according to one or more embodiments may include a substrate, a first electrode and a third electrode integrally formed to be electrically connected to each other, and a second electrode and a fourth electrode integrally formed to be electrically connected to each other, the first, second, third, and fourth electrodes being spaced apart from each other above the substrate, a first dummy electrode and a second dummy electrode spaced apart from each other above the substrate, and electrically insulated from the first, second, third, and fourth electrodes, and a light-emitting element electrically connected to the first and second electrodes.

### CROSS-REFERENCE TO RELATED APPLICATION

The application claims priority to, and the benefit of, Korean Patent Application No. 10-2023-0042654, filed Mar. 31, 2023, in the Korean Intellectual Property Office, the entire contents of which are incorporated herein by reference.

### BACKGROUND

### Technical Field

The disclosure relates to a display device and a repair method thereof.

### Description of the Related Art

Recently, as interest in information display is increasing, research and development on display devices are continuously conducted.

### SUMMARY

Embodiments may provide a display with improved reliability by reducing or preventing the likelihood of a dark spot defect in a pixel, and a repair method thereof.

One or more embodiments provide a display device including a substrate, a first electrode and a third electrode integrally formed to be electrically connected to each other, and a second electrode and a fourth electrode integrally formed to be electrically connected to each other, the first, second, third, and fourth electrodes being spaced apart from each other above the substrate, a first dummy electrode and a second dummy electrode spaced apart from each other above the substrate, and electrically insulated from the first, second, third, and fourth electrodes, and a light-emitting element electrically connected to the first and second electrodes.

The display device may further include a pixel circuit layer above the substrate, and including a transistor electrically connected to the third electrode, and a 1 common line above the substrate, and integrally formed with the second and fourth electrodes to be electrically connected to the second and fourth electrodes.

The second electrode and the fourth electrode may branch from the common line in one direction.

The first electrode may include two or more first sub-electrodes spaced apart from each other, wherein the second electrode includes two or more second sub-electrodes spaced apart from each other.

The first sub-electrodes may be electrically connected to each other, and the second sub-electrodes are electrically connected to each other.

The display device may further include a first connection line above the substrate, and electrically connecting the first sub-electrodes, and a second connection line above the substrate, and electrically connecting the second sub-electrodes.

The first sub-electrodes may have widths that are different from that of the third electrode, wherein the second sub-electrodes have widths that are different from that of the fourth electrode.

The first sub-electrodes may have same respective widths, wherein the second sub-electrodes have same respective widths.

At least one of the first sub-electrodes may have a different width than others of the first sub-electrodes, wherein at least one of the second sub-electrodes has a different width than others of the second sub-electrodes.

The light-emitting element may have a horizontal structure including a first end and a second end above a same plane, and may include a semiconductor structure including a first semiconductor layer, an active layer above the first semiconductor layer, and a second semiconductor layer above the active layer, a first contact electrode on the semiconductor structure, and at the second end to be electrically connected to the first semiconductor layer, and a second contact electrode on the semiconductor structure, and at the first end to be electrically connected to the second semiconductor layer. 1 [0015] The first semiconductor layer may include an n-type semiconductor layer doped with an n-type dopant, wherein the second semiconductor layer includes a p-type semiconductor layer doped with a p-type dopant.

The display device may further include a first bonding electrode between the first end of the light-emitting element and the first sub-electrodes, and coupling the light-emitting element and the first sub-electrodes, and a second bonding electrode between the second end of the light-emitting element and the second sub-electrodes, and coupling the light-emitting element and the second sub-electrodes.

The display device may further include a cover layer above the light-emitting element, an optical layer above the cover layer, and an overcoat layer above the optical layer.

One or more embodiments provide a display device including a substrate, a first electrode above the substrate, and including two or more first sub-electrodes, a second electrode above the substrate, and including two or more second sub-electrodes, a third electrode spaced apart from the first and second electrodes, a fourth electrode spaced apart from the first, second, and third electrodes, a light-emitting element electrically connected to the first electrode and to the second electrode, a first bridge electrode having one end electrically connected to the second sub-electrodes, and another end electrically connected to the third electrode, and a second bridge electrode having one end electrically connected to the first sub-electrodes, and another end electrically connected to the fourth electrode.

The light-emitting element may include a second end electrically connected to the first sub-electrodes, and a first end electrically connected to the second sub-electrodes, the first end and the second end being on a same plane, wherein a p-type semiconductor layer is at the first end, and an n-type semiconductor layer is at the second end.

The display device may further include a pixel circuit layer above the substrate, and including a transistor electrically connected to the third electrode, and a 1 common line above the substrate, and electrically connected to the fourth electrode, wherein the first sub-electrodes are electrically connected to the fourth electrode and the common line through the second bridge electrode, and wherein the second sub-electrodes are electrically connected to the third electrode and the transistor through the first bridge electrode.

The first sub-electrodes may be electrically connected to each other, wherein the second sub-electrodes are electrically connected to each other.

In a repair method of a display device according to one or more embodiments, the display device may include a substrate, a first electrode above the substrate and including two or more first sub-electrodes, a second electrode electrically separated from the first electrode above the substrate and including two or more second sub-electrodes, a third electrode electrically connected to the first sub-electrodes, a fourth electrode electrically connected to the second sub-electrodes, a first dummy electrode and a second dummy electrode spaced apart from each other above the substrate, and a light-emitting element electrically connected to the first sub-electrodes and the second sub-electrodes, the repair method including electrically separating the first sub-electrodes and the third electrode from each other using a laser, electrically separating the second sub-electrodes and the fourth electrode from each other using a laser, forming a first bridge electrode connecting one end of the first dummy electrode to the second sub-electrodes, and connecting another end of the first dummy electrode to the third electrode through laser welding, and forming a second bridge electrode connecting one end of the second dummy electrode to the first sub-electrodes, and connecting another end of the second dummy electrode to the fourth electrode through laser welding.

The light-emitting element may include a second end electrically connected to the first sub-electrodes and the third electrode, and a first end electrically connected to the second sub-electrodes and the fourth electrode, wherein the second end and the 1 first end are on a same plane, wherein a p-type semiconductor layer is at the first end, and wherein an n-type semiconductor layer is at the second end.

The display device may further include a pixel circuit layer above the substrate, and including a transistor electrically connected to the third electrode, and a common line above the substrate, and electrically connected to the fourth electrode, wherein the first sub-electrodes are electrically connected to the fourth electrode and the common line through the second bridge electrode, and wherein the second sub-electrodes are electrically connected to the third electrode and the transistor through the first bridge electrode.

### BRIEF DESCRIPTION OF THE DRAWINGS

The accompanying drawings, which are included to provide a further understanding of the present disclosure, and are incorporated in and constitute a part of this specification, illustrate embodiments of the present disclosure, and, together with the description, serve to explain aspects of the present disclosure.

FIG. 1 is a schematic plan view illustrating a display device according to one or more embodiments.

FIG. 2 is a schematic cross-sectional view of a display panel of FIG. 1.

FIG. 3 is a schematic circuit diagram illustrating an electrical connection relationship of components included in each of pixels shown in FIG. 1.

FIG. 4 is a schematic plan view illustrating a sub-pixel according to one or more embodiments.

FIG. 5 is a schematic cross-sectional view taken along the line I˜I′ in FIG. 4.

FIGS. 6 to 10 are schematic plan views illustrating sub-pixels according to embodiments.

FIGS. 11A and 11B are schematic plan views illustrating a state in which a light-emitting element is transferred in the sub-pixel of FIG. 4.

FIG. 12 is a schematic cross-sectional view taken along the line II˜II′ in FIG. 11A.

FIG. 13 is a schematic cross-sectional view of a light-emitting element of FIG. 12.

FIG. 14 is a schematic cross-sectional view taken along the line II˜II′ in FIG. 11A and illustrates a sub-pixel according to one or more embodiments.

FIG. 15 is a schematic cross-sectional view taken along the line II˜II′ in FIG. 11A and illustrates a sub-pixel including a defective light-emitting element in which a defect occurs.

FIGS. 16 and 17 are schematic plan views illustrating a method of repairing the defective light-emitting element of FIG. 15.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, 1 equivalents, and replacements within the idea and technical scope of the present disclosure. Further, each of the features of the various embodiments of the present disclosure may be combined or combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes 1 place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second 1 object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or 1 layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of 1 elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement 1 of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

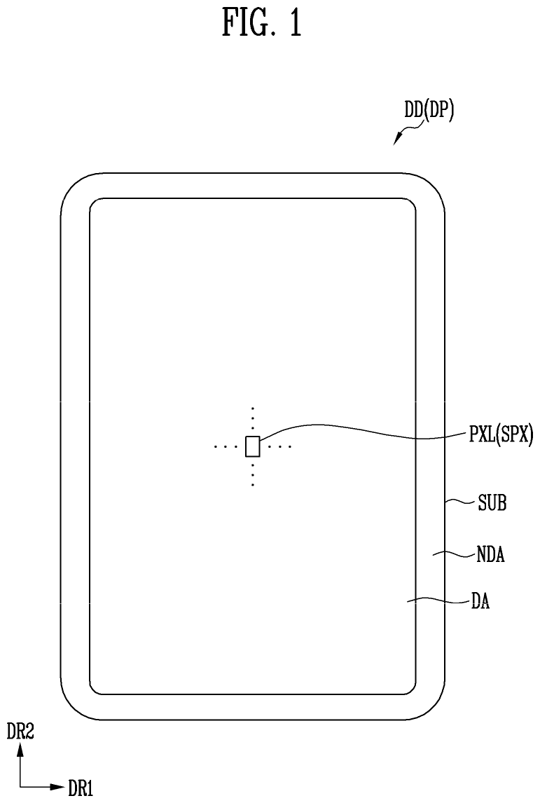

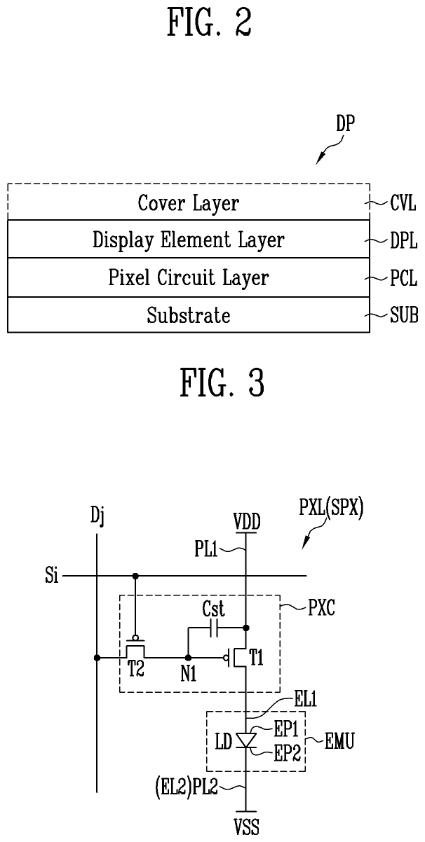

FIG. 1 is a schematic plan view illustrating a display device DD according to one or more embodiments. FIG. 2 is a schematic cross-sectional view of a display panel DP of FIG. 1.

In FIGS. 1 and 2, for convenience of description, a structure of the display device DD, for example, the display panel DP provided in the display device DD, is briefly shown centering on a display area DA where an image is displayed.

Referring to FIGS. 1 and 2, the display panel DP (or display device DD) according to one or more embodiments may be provided in various shapes. For example, the display panel DP may have a rectangular plate shape having two pairs of sides parallel to each other. However, the disclosure is not limited thereto. In case that the display panel DP is provided in a rectangular plate shape, among the two pairs of sides, one pair of sides may be provided longer than the other pair of sides. In FIG. 1, a direction in which long sides extend is indicated as a second direction DR2, and a direction in which short side extend is indicated as a first direction DR1.

At least a portion of the display panel DP may have flexibility, and may be folded at the flexible portion, but the disclosure is not limited thereto.

The display panel DP may display an image. The display panel DP may be a self-emitting light display panel, or a non-emitting light display panel.

The display panel DP may include a substrate SUB and pixels PXL (or sub-pixels SPX) provided in the substrate SUB.

The substrate SUB may include a transparent insulating material through which light is transmitted, but the disclosure is not limited thereto. The substrate SUB may be a rigid substrate or a flexible substrate.

The rigid substrate may be, for example, one of a glass substrate, a quartz substrate, a glass ceramic substrate, and a crystalline glass substrate.

The flexible substrate may be one of a film substrate including a polymeric organic material and a plastic substrate. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and/or cellulose acetate propionate. However, the disclosure is not limited thereto.

One area of the substrate SUB may be provided as the display area DA where the pixels PXL may be located. The remaining area of the substrate SUB may be provided as a non-display area NDA. For example, the substrate SUB may include the display area DA including pixel areas in which each pixel PXL (or sub-pixel SPX) is located, and the non-display area NDA located around the display area DA (or adjacent to the display area DA).

The non-display area NDA may be located adjacent to the display area DA. The non-display area NDA may be provided in at least one side of the display area DA. For example, the non-display area NDA may surround the periphery (or edge) of the display area DA. A wiring part electrically connected to each pixel PXL, and a driver electrically connected to the wiring part for driving the pixel PXL, may be provided in the non-display area NDA.

The pixel PXL may be provided in the display area DA of the substrate SUB. The pixel PXL may include a light-emitting element emitting white light and/or color light, and may include a pixel circuit for driving the light-emitting element. The pixel circuit may include at least one transistor electrically connected to the light-emitting element. The pixel PXL may emit light of one color among red, green, and/or blue, but the disclosure is not limited thereto. The pixel PXL may emit light of one color among cyan, magenta, yellow, and/or white.

The pixels PXL may be provided in plurality, and may be arranged in a matrix form along pixel rows extending in the first direction DR1, and along pixel columns extending in the second direction DR2 crossing the first direction DR1. The arrangement form of the pixels PXL is not particularly limited, and the pixels PXL may be arranged in various forms. According to one or more embodiments, if a plurality of pixels PXL are provided, they may be provided to have different areas (or sizes). For example, in the case of pixels PXL emitting light of different colors, areas (or sizes) and/or shapes of the pixels PXL may be provided differently for each color.

The driver may control the driving of the pixel PXL by providing a signal (e.g., a predetermined signal) and a voltage (e.g., predetermined voltage) to each pixel PXL through the wiring part.

The display panel DP (or pixel PXL) may include a substrate SUB, a pixel circuit layer PCL, a display element layer DPL, and a cover layer CVL.

The pixel circuit layer PCL may be located on the substrate SUB, and may include a transistor and signal lines electrically connected to the transistor. For example, the transistor may have a structure in which a semiconductor pattern and a gate electrode are sequentially stacked with an insulating layer interposed therebetween. The semiconductor pattern may include amorphous silicon, polysilicon, low temperature polysilicon, an organic semiconductor, and/or an oxide semiconductor. The gate electrode may include at least one of aluminum (Al), copper (Cu), titanium (Ti), and/or molybdenum (Mo), but the disclosure is not limited thereto. Also, the pixel circuit layer PCL may include at least one insulating layer.

The display element layer DPL may be located on the pixel circuit layer PCL. The display element layer DPL may include a light-emitting element for emitting light.

The cover layer CVL may be selectively located on the display element layer DPL.

The cover layer CVL may be provided to cover the display element layer DPL, and may protect the display element layer DPL from external impact. The cover layer CVL may be an encapsulation substrate or an encapsulation film composed of a multilayer. In case that the cover layer CVL is the encapsulation film, it may include an inorganic film and/or an organic film. For example, the cover layer CVL may have a structure in which an inorganic layer, an organic layer, and an inorganic layer are sequentially stacked. The cover layer CVL may reduce or prevent air and moisture penetrating into the display element layer DPL and the pixel circuit layer PCL from the outside.

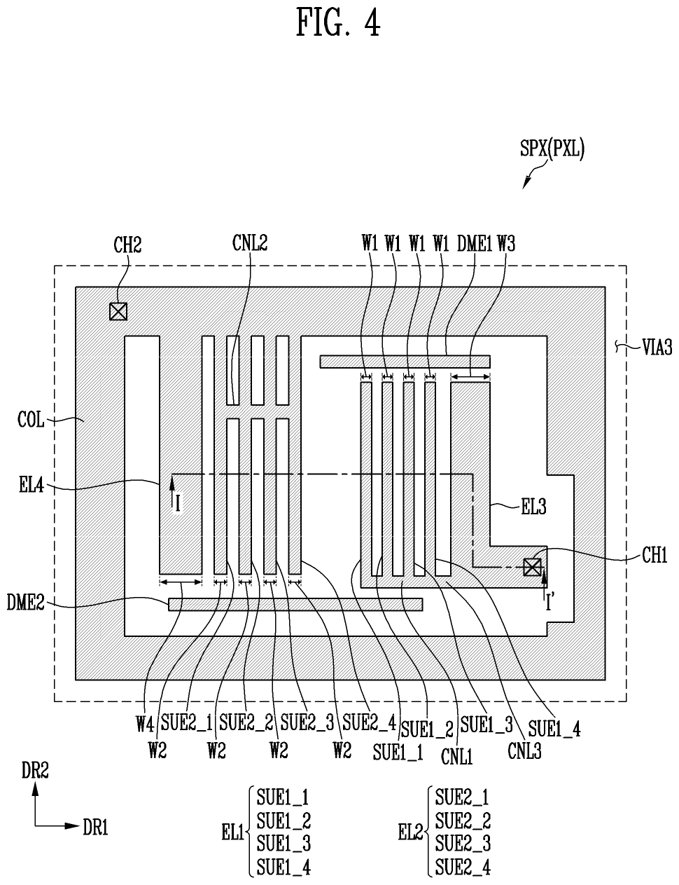

FIG. 3 is a schematic circuit diagram illustrating an electrical connection relationship of components included in each of pixels PXL shown in FIG. 1.

In FIG. 3, for convenience of description, a pixel PXL (or sub-pixel SPX) positioned in an i-th pixel row (or i-th horizontal line) and a j-th pixel column is shown for example, where i and j may be natural numbers.

Referring to FIGS. 1 to 3, the pixel PXL (or sub-pixel SPX) may include an emission component EMU that generates light having a luminance corresponding to a data signal. Also, the pixel PXL may include a pixel circuit PXC for driving the emission component EMU.

The emission component EMU may include a light-emitting element LD electrically connected between a first power source line PL1 receiving a voltage of a first driving power source VDD, and a second power source line PL2 receiving a voltage of a second driving power source VSS. For example, the emission component EMU may include a first electrode EL1 electrically connected to the first driving power source VDD via the pixel circuit PXC and via the first power source line PL1, may include a second electrode EL2 electrically connected to the second driving power source VSS via the second power source line PL2, and may include the light-emitting element LD electrically connected between the first electrode EL1 and the second electrode EL2. In one or more embodiments, the first electrode EL1 may be an anode, and the second electrode EL2 may be a cathode.

The light-emitting element LD may include a first end EP1 electrically connected to the first electrode EL1, and may include a second end EP2 electrically connected to the second electrode EL2. The first driving power source VDD and the second driving power source VSS may have different potentials. In this case, a potential difference between the first and second driving power sources VDD and VSS may be set to be higher than or equal to a threshold voltage of the light-emitting element LD during an emission period of the pixel PXL.

As described above, the light-emitting element LD may constitute an effective light source of the emission component EMU.

The light-emitting element LD may emit light with a luminance corresponding to a driving current supplied through the pixel circuit PXC. For example, during each frame period, the pixel circuit PXC may supply the driving current corresponding to a grayscale value of corresponding frame data to the emission component EMU. The driving current supplied to the emission component EMU may flow through the light-emitting element LD. Accordingly, the emission component EMU may emit light while the light-emitting element LD emits light with a luminance corresponding to the driving current.

In case that the pixel PXL (or sub-pixel SPX) is positioned in the i-th pixel row and the j-th pixel column in the display area DA, the pixel circuit PXC of the pixel PXL may be electrically connected to an i-th scan line Si and a j-th data line Dj.

The pixel circuit PXC may include a first transistor T1, a second transistor T2, and a storage capacitor Cst.

The first transistor T1 may be a driving transistor for controlling the driving current applied to the light-emitting element LD, and may be electrically connected between the first driving power source VDD and the light-emitting element LD. For example, a first terminal of the first transistor T1 may be electrically connected to the first driving power source VDD through the first power source line PL1, a second terminal of the first transistor T1 may be electrically connected to the light-emitting element LD, and a gate electrode of the first transistor T1 may be electrically connected to a first node N1. The first transistor T1 may control the amount of driving current applied from the first driving power source VDD to the light-emitting element LD according to a voltage applied to the first node N1. The first terminal of the first transistor T1 may be a source electrode, and the second terminal of the first transistor T1 may be a drain electrode.

The second transistor T2 may be a switching transistor that selects and activates the pixel PXL in response to a scan signal, and may be electrically connected between the j-th data line Dj and the first node N1. A first terminal of the second transistor T2 may be electrically connected to the j-th data line Dj, a second terminal of the second transistor T2 may be electrically connected to the first node N1 (or the gate electrode of the first transistor T1), and a gate electrode of the second transistor T2 may be electrically connected to the i-th scan line Si. The first terminal and the second terminal of the second transistor T2 may be different terminals. For example, if the first terminal is a source electrode, the second terminal may be a drain electrode.

The second transistor T2 may be turned on if the scan signal of a gate-on voltage (for example, a low level voltage) is supplied from the i-th scan line Si to electrically connect the j-th data line Dj and the first node N1. In this case, the data signal of a corresponding frame may be supplied to the j-th data line Dj. Accordingly, 1 the data signal may be transmitted to the first node N1. The data signal transmitted to the first node N1 may be charged in the storage capacitor Cst.

One electrode of the storage capacitor Cst may be electrically connected to the first driving power source VDD, and the other electrode may be electrically connected to the first node N1. The storage capacitor Cst may charge a voltage corresponding to the data signal supplied to the first node N1, and may maintain the charged voltage until the data signal of the next frame is supplied.

FIG. 3 shows the pixel circuit PXC including the second transistor T2 for transferring the data signal to the pixel PXL (or sub-pixel SPX), the storage capacitor Cst for storing the data signal, and the first transistor T1 for supplying the driving current corresponding to the data signal to the light-emitting element LD. However, the disclosure is not limited thereto. A structure of the pixel circuit PXC may be variously changed. For example, the pixel circuit PXC may further include at least one transistor element, such as a transistor element for compensating a threshold voltage of the first transistor T1, a transistor element for initializing the first node N1, and/or a transistor element for controlling the emission time of the light-emitting element LD, or other circuit elements, such as a boosting capacitor for boosting the voltage of the first node N1.

In the following embodiments, for convenience of description, a horizontal direction (or X-axis direction) on a plane (e.g., in plan view) is indicated as a first direction DR1, a vertical direction (or Y-axis direction) on a plane is indicated as a second direction DR2, and a vertical direction on a cross section is indicated as a third direction DR3.

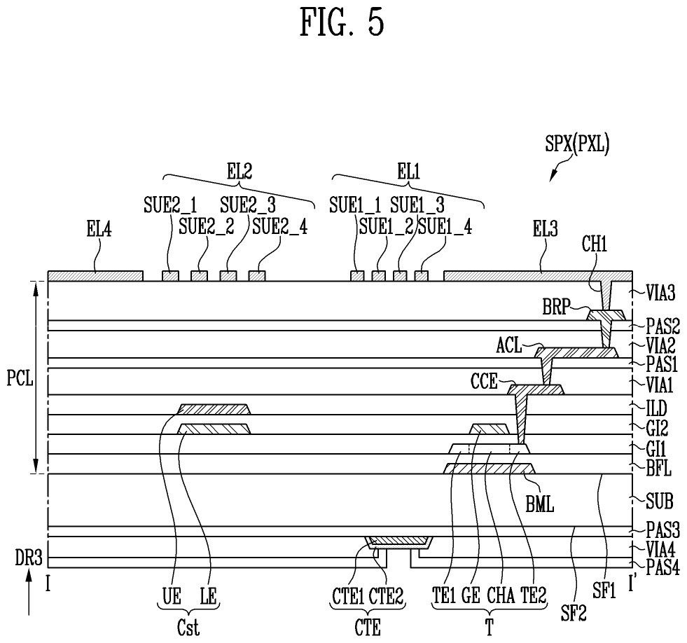

FIG. 4 is a schematic plan view illustrating a sub-pixel SPX according to one or more embodiments.

In FIG. 4, for convenience of description, illustration of components located under a third via layer VIA3 will be omitted.

Referring to FIGS. 1 to 4, the sub-pixel SPX (or pixel PXL) may include a first electrode EL1, a second electrode EL2, a third electrode EL3, and a fourth electrode EL4 spaced apart from each other on the third via layer VIA3. In addition, the sub-pixel SPX may further include a common line COL, a first dummy electrode DME1, and a second dummy electrode DME2.

The common line COL may have a closed loop shape surrounding the first to fourth electrodes EL1, EL2, EL3, and EL4 and the first and second dummy electrodes DME1 and DME2 in one area of the display area DA where the sub-pixels SPX are located. However, the disclosure is not limited thereto, and the common line COL may be provided in various shapes. The common line COL may be electrically connected to the second power source line PL2 of the pixel circuit PXC described with reference to FIG. 3 through a second contact hole CH2. Accordingly, the voltage of the second driving power source VSS may be supplied to the common line COL.

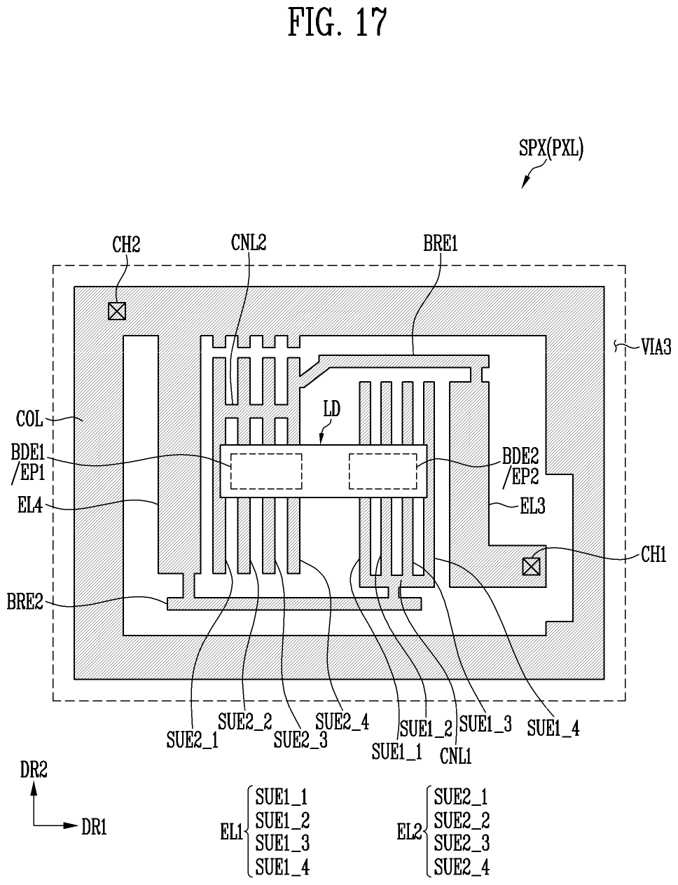

The first dummy electrode DME1 may extend in the first direction DR1, and may be spaced apart from the common line COL, the second dummy electrode DME2, and the first to fourth electrodes EL1, EL2, EL3, and EL4. In a process of repairing a dark spot defect of the sub-pixel SPX that occurs if the light-emitting element LD (refer to FIG. 3) is connected in a reverse direction, the first dummy electrode DME1 may be formed as a first bridge electrode BRE1 (refer to FIG. 17) electrically connecting the third electrode EL3 and the second electrode EL2 through a laser welding process.

The second dummy electrode DME2 may extend in the first direction DR1 and may be spaced apart from the common line COL, the first to fourth electrodes EL1, EL2, EL3, and EL4, and the first dummy electrode DME1. In a process of repairing a dark spot defect of the sub-pixel SPX that occurs if the light-emitting element LD is connected in a reverse direction, the second dummy electrode DME2 may be formed as a second bridge electrode BRE2 (refer to FIG. 17) for electrically connecting the first electrode EL1 and the fourth electrode EL4 through a laser welding process.

The first electrode EL1 may be spaced apart from the common line COL. The first electrode EL1 may be electrically connected to the third electrode EL3 through a third connection line CNL3. The first electrode EL1 may have a bar shape extending in the second direction DR2, but the disclosure is not limited thereto.

In one or more embodiments, the first electrode EL1 may include at least two first sub-electrodes. For example, the first electrode EL1 may include four first sub-electrodes. The four first sub-electrodes may include a (1-1)th sub-electrode SUE1_1, a (1-2)th sub-electrode SUE1_2, a (1-3)th sub-electrode SUE1_3, and a (1-4)th sub-electrode SUE1_4. The (1-1)th sub-electrode SUE1_1, the (1-2)th sub-electrode SUE1_2, the (1-3)th sub-electrode SUE1_3, and the (1-4)th sub-electrode SUE1_4 may be arranged along the first direction DR1 and may be electrically connected to each other through a first connection line CNL1.

The first connection line CNL1 may extend in the first direction DR1 and may be positioned between adjacent first sub-electrodes to electrically connect the first sub-electrodes to each other. The first connection line CNL1 may be positioned, for example, between the (1-1)th sub-electrode SUE1_1 and the (1-2)th sub-electrode SUE1_2, between the (1-2)th sub-electrode SUE1_2 and the (1-3)th sub-electrodes SUE1_3, and/or between the (1-3)th sub-electrodes SUE1_3 and the (1-4)th sub-electrodes SUE1_4, respectively. The first connection line CNL1 may be formed integrally with the (1-1)th sub-electrode SUE1_1, the (1-2)th sub-electrode SUE1_2, the (1-3)th sub-electrode SUE1_3, and the (1-4)th sub-electrode SUE1_4.

A width W1 of the (1-1)th sub-electrode SUE1_1 (for example, a width in the first direction DR1), a width W1 of the (1-2)th sub-electrode SUE1_2 (for example, a width in the first direction DR1), a width W1 of the (1-3)th sub-electrode SUE1_3 (for example, a width in the first direction DR1), and a width W1 of the (1-4)th sub-electrode SUE1_4 (for example, a width in the first direction DR1) may be the same, but the disclosure is not limited thereto. According to one or more embodiments, the width W1 of the (1-1)th sub-electrode SUE1_1, the width W1 of the (1-2)th sub-electrode SUE1_2, the width W1 of the (1-3)th sub-electrode SUE1_3, and the width W1 of the (1-4)th sub-electrodes SUE1_4 may be different from one or more of each other.

The second electrode EL2 may be branched from the common line COL along the second direction DR2. The second electrode EL2 may be formed integrally with the common line COL and electrically connected to the common line COL. The second electrode EL2 may have a bar shape extending in the second direction DR2, but the disclosure is not limited thereto. Because the common line COL is electrically connected to the second power source line PL2 through the second contact hole CH2, the second electrode EL2 may be electrically connected to the second power source line PL2. In one or more embodiments, the second electrode EL2 may be the cathode electrically connected to the second end EP2 (refer to FIG. 3) of the light-emitting element LD.

In one or more embodiments, the second electrode EL2 may include at least two second sub-electrodes. For example, the second electrode EL2 may include four second sub-electrodes. The four second sub-electrodes may include a (2-1)th sub-electrode SUE2_1, a (2-2)th sub-electrode SUE2_2, a (2-3)th sub-electrode SUE2_3, and a (2-4)th sub-electrode SUE2_4. The (2-1)th sub-electrode SUE2_1, the (2-2)th sub-electrode SUE2_2, the (2-3)th sub-electrode SUE2_3, and the (2-4)th sub-electrode SUE2_4 may be arranged along the first direction DR1, and may be electrically connected to each other through a second connection line CNL2.

The second connection line CNL2 may extend in the first direction DR1, and may be positioned between adjacent second sub-electrodes to electrically connect the second sub-electrodes to each other. The second connection line CNL2 may be positioned, for example, between the (2-1)th sub-electrode SUE2_1 and the (2-2)th sub-electrode SUE2_2, between the (2-2)th sub-electrode SUE2_2 and the (2-3)th sub-electrode SUE2_3, and between the (2-3)th sub-electrode SUE2_3 and the (2-4)th sub-electrode SUE2_4, respectively. The second connection line CNL2 may be 1 formed integrally with the (2-1)th sub-electrode SUE2_1, the (2-2)th sub-electrode SUE2_2, the (2-3)th sub-electrode SUE2_3, and the (2-4)th sub-electrode SUE2_4.

A width W2 of the (2-1)th sub-electrode SUE2_1 (for example, a width in the first direction DR1), a width W2 of the (2-2)th sub-electrode SUE2_2 (for example, a width in the first direction DR1), a width W2 of the (2-3)th sub-electrode SUE2_3 (for example, a width in the first direction DR1), and a width W2 of the (2-4)th sub-electrode SUE2_4 (for example, a width in the first direction DR1) may be the same, but the disclosure is not limited thereto. According to one or more embodiments, the width W2 of the (2-1)th sub-electrode SUE2_1, the width W2 of the (2-2)th sub-electrode SUE2_2, the width W2 of the (2-3)th sub-electrode SUE2_3, and the width W2 of the (2-4)th sub-electrode SUE2_4 may be different from one or more of each other.

In a plan view, the (1-1)th sub-electrode SUE1_1 and the (2-4)th sub-electrode SUE2_4 may be located to face each other in the first direction DR1, but the disclosure is not limited thereto.

The third electrode EL3 may be spaced apart from the first electrode EL1, the second electrode EL2, and the common line COL. The third electrode EL3 may be electrically connected to the first electrode EL1 through the third connection line CNL3. For example, the third electrode EL3 may be electrically connected to the (1-4)th sub-electrode SUE1_4 through the third connection line CNL3.

The third connection line CNL3 may extend in the first direction DR1, and may be positioned between the third electrode EL3 and the (1-4)th sub-electrode SUE1_4 to electrically connect the third electrode EL3 and the (1-4)th sub-electrode SUE1_4. In one or more embodiments, the third electrode EL3, the third connection line CNL3, and the (1-4)th sub-electrode SUE1_4 (or the first electrode EL1) may be integrally formed.

The third electrode EL3 may be electrically connected to some component of the pixel circuit PXC described with reference to FIG. 3, for example, to the first transistor T1 through a first contact hole CH1. Because the third electrode EL3 is electrically connected to the first electrode EL1 through the third connection line CNL3, the first electrode EL1 may be electrically connected to the first transistor T1. In one or more embodiments, the first electrode EL1 may be the anode electrically connected to the first end EP1 (refer to FIG. 3) of the light-emitting element LD.

The third electrode EL3 may include a first portion extending along the first direction DR1 and a second portion extending along the second direction DR2. A width W3 of the second portion of the third electrode EL3 (for example, a width in the first direction DR1) may be greater than the width W1 of the first sub-electrodes, but the disclosure is not limited thereto.

The fourth electrode EL4 may be spaced apart from the first to third electrodes EL1, EL2, and EL3. The fourth electrode EL4 may be branched from the common line COL along the second direction DR2. In one or more embodiments, the common line COL, the second electrode EL2, and the fourth electrode EL4 may be integrally formed. The fourth electrode EL4 may be electrically connected to the second power source line PL2.

The fourth electrode EL4 may have a bar shape extending in the second direction DR2, but the disclosure is not limited thereto. A width W4 of the fourth electrode EL4 (for example, a width in the first direction DR1) may be greater than the width W2 of the second sub-electrodes, but the disclosure is not limited thereto. According to one or more embodiments, the width W2 of the second sub-electrodes may be greater than the width W4 of the fourth electrode EL4.

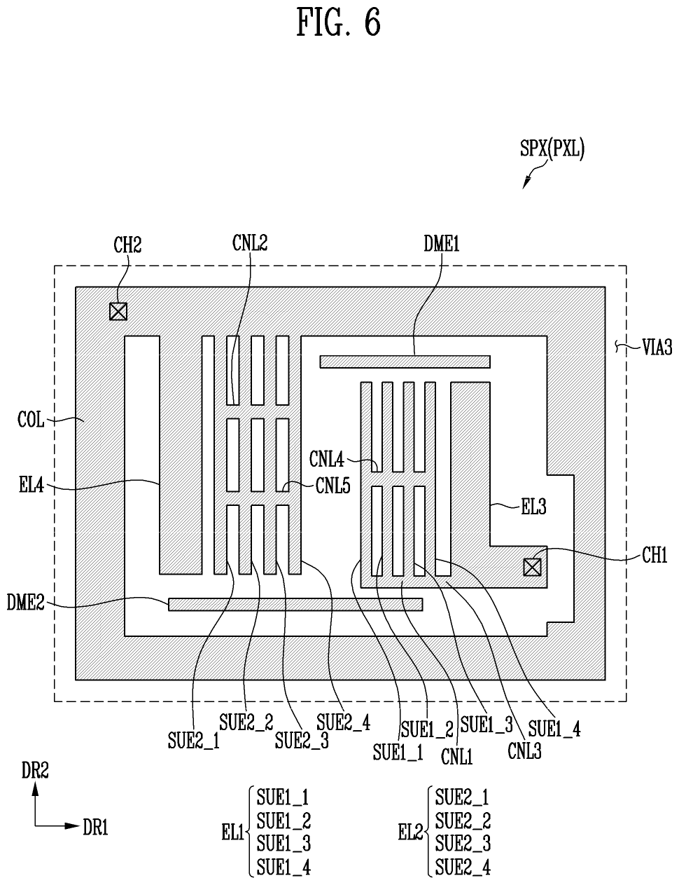

Hereinafter, a stacked structure (or cross-sectional structure) of the sub-pixel SPX (or pixel PXL) according to the above-described embodiments will be mainly described with reference to FIG. 5.

FIG. 5 is a schematic cross-sectional view taken along the line I˜I′ in FIG. 4.

In FIG. 5, one sub-pixel SPX (or pixel PXL) is shown simplified in such a way that each electrode is shown as a single-layered electrode and each insulating layer is shown as a single-layered insulating layer, but the disclosure is not limited thereto.

Referring to FIGS. 1 to 5, the sub-pixel SPX may include the substrate SUB, the pixel circuit layer PCL located on the substrate SUB, and electrodes located on the pixel circuit layer PCL.

The substrate SUB may include a transparent insulating material through which light is transmitted. The substrate SUB may be a rigid substrate or a flexible substrate. The substrate SUB may include a first surface SF1 and a second surface SF2 opposite to each other in the third direction DR3. The first surface SF1 may be a mounting surface on which the light-emitting element LD (refer to FIG. 3) is mounted, and the second surface SF2 may be a surface on which an intermediate electrode CTE electrically connected to a flexible film is located.

The sub-pixel SPX (or pixel PXL) may include a third passivation layer PAS3, a fourth via layer VIA4, and a fourth passivation layer PAS4 sequentially stacked on, or below, the second surface SF2 of the substrate SUB in a direction opposite to the third direction DR3.

The third passivation layer PAS3 may be positioned on/below the second surface SF2 of the substrate SUB, may protect the second surface SF2 of the substrate SUB, and may planarize the second surface SF2. The third passivation layer PAS3 may be an inorganic insulating layer including an inorganic material. The third passivation layer PAS3 may include at least one of silicon nitride (SiNₓ), silicon oxide (SiOₓ), silicon oxynitride (SiOₓN_{y}), and/or aluminum oxide (AlOₓ).

The intermediate electrode CTE may be located on the third passivation layer PAS3. The intermediate electrode CTE may supply a voltage or signal received from the flexible film to a side connection line through a lead line. The intermediate electrode CTE may be electrically connected to the flexible film through a conductive member (or connection film).

The intermediate electrode CTE may include a first intermediate electrode CTE1 and a second intermediate electrode CTE2. The first intermediate electrode CTE1 may be located on one surface (or lower surface) of the third passivation layer PAS3. The first intermediate electrode CTE1 may be a single layer or multiple layers made of at least one of molybdenum (Mo), aluminum (Al), chromium (Cr), gold (Au), titanium (Ti), nickel (Ni), neodymium (Nd), copper (Cu), and/or an alloy thereof. The second intermediate electrode CTE2 may be located on one surface (or lower surface) of the first intermediate electrode CTE1. The second intermediate electrode CTE2 may include a transparent conductive material (TCO), such as ITO or IZO.

The fourth via layer VIA4 may be located on/below the third passivation layer PAS3 and a portion of the intermediate electrode CTE. The fourth via layer VIA4 may be an organic insulating layer including an organic material. The fourth via layer VIA4 may include at least one of a polyacrylates resin, an epoxy resin, a phenolic resin, a polyamides resin, a polyimide resin, an unsaturated polyesters resin, a poly-phenylen ethers resin, a poly-phenylene sulfides resin, and/or a benzocyclobutene resin. The fourth via layer VIA4 may planarize the second surface SF2 of the substrate SUB.

The fourth passivation layer PAS4 may be located on the fourth via layer VIA4 and the intermediate electrode CTE to protect the intermediate electrode CTE. The fourth passivation layer PAS4 may include a same material as the third passivation layer PAS3, or may include a suitable material selected from materials disclosed as a material constituting the third passivation layer PAS3.

The pixel circuit layer PCL may be provided and/or formed on the first surface SF1 of the substrate SUB.

The pixel circuit PXC may be located in the pixel circuit layer PCL. The pixel circuit layer PCL may include at least one insulating layer located on the first surface SF1 of the substrate SUB. For example, the pixel circuit layer PCL may include a buffer layer BFL, a first gate-insulating layer GI1, a second gate-insulating layer GI2, an interlayer insulating layer ILD, a first via layer VIA1, a first passivation layer PAS1, a second via layer VIA2, a second passivation layer PAS2, and the third via layer VIA3 sequentially stacked on the first surface SF1 of the substrate SUB along the third direction DR3.

The buffer layer BFL may be located entirely on (e.g., above) the first surface SF1 of the substrate SUB. The buffer layer BFL may reduce or prevent impurities diffusing into a transistor T. The buffer layer BFL may be an inorganic insulating layer including an inorganic material. The buffer layer BFL may include at least one of silicon nitride (SiNₓ), silicon oxide (SiOₓ), and silicon oxynitride (SiOₓN_{y}), or at least one of metal oxide, such as aluminum oxide (AlₓO_{y}). The buffer layer BFL may be provided as a single layer or as multiple layers including a double layer. In case that the buffer layer BFL is provided in multiple layers, each layer may be formed of the same material or of different materials. The buffer layer BFL may be omitted depending on the material of the substrate SUB and process conditions.

The first gate-insulating layer GI1 may be entirely located on/above the buffer layer BFL, but the disclosure is not limited thereto. According to one or more embodiments, the first gate-insulating layer GI1 may be partially located on/above the buffer layer BFL. The first gate-insulating layer GI1 may include a same material as the buffer layer BFL described above, or may include a suitable material selected from materials disclosed as a material constituting the buffer layer BFL. For example, the first gate-insulating layer GI1 may include an inorganic insulating layer including an inorganic material.

The second gate-insulating layer GI2 may be entirely located on/above the first gate-insulating layer GI1, but the disclosure is not limited thereto. According to one or more embodiments, the second gate-insulating layer GI2 may be partially located on/above the first gate-insulating layer GI1. The second gate-insulating layer GI2 may include a same material as the first gate-insulating layer GI1. For example, the second gate-insulating layer GI2 may be an inorganic insulating layer including an inorganic material.

The interlayer insulating layer ILD may be provided and/or formed entirely on/above the second gate-insulating layer GI2. The interlayer insulating layer ILD may include a same material as the second gate-insulating layer GI2 or may include one or more suitable materials selected from materials disclosed as a material constituting the buffer layer BFL.

The first via layer VIA1 may be provided and/or formed entirely on/above the interlayer insulating layer ILD. The first via layer VIA1 may be an inorganic insulating layer including an inorganic material or an organic insulating layer including an organic material. The inorganic insulating layer may include, for example, at least one of silicon oxide (SiOₓ), silicon nitride (SiNₓ), silicon oxynitride (SiOₓN_{y}), and/or aluminum oxide (AlOₓ). The organic insulating layer may include, for example, at least one of a polyacrylates resin, an epoxy resin, a phenolic resin, a polyamides resin, a polyimides rein, an unsaturated polyesters resin, a poly-phenylen ethers resin, a poly-phenylene sulfides resin, and/or a benzocyclobutene resin. The first via layer VIA1 may have a flat surface to alleviate a step difference caused by components located thereunder. The first via layer VIA1 may include an organic insulating layer including an organic material.

The first passivation layer PAS1 may be provided and/or formed entirely on/above the first via layer VIA1. The first passivation layer PAS1 may be an inorganic insulating layer including an inorganic material. The first passivation layer PAS1 may include at least one of silicon nitride (SiNₓ), silicon oxide (SiOₓ), silicon oxynitride (SiOₓN_{y}), and/or aluminum oxide (AlOₓ).

The second via layer VIA2 may be provided and/or formed entirely on/above the first passivation layer PAS1. The second via layer VIA2 may include a same material as the first via layer VIA1 or may include a suitable material selected from materials disclosed as a material constituting the first via layer VIA1. For example, the second via layer VIA2 may be an organic insulating layer including an organic material.

The second passivation layer PAS2 may be provided and/or formed entirely on/above the second via layer VIA2. The second passivation layer PAS2 may include a same material as the first passivation layer PAS1. The second passivation layer PAS2 may be an inorganic insulating layer including an inorganic material.

The third via layer VIA3 may be provided and/or formed entirely on/above the second passivation layer PAS2. The third via layer VIA3 may include a same material as the first via layer VIA1. For example, the third via layer VIA3 may be an organic insulating layer including an organic material.

The pixel circuit layer PCL may include at least one conductive layer located between the insulating layers described above. For example, the pixel circuit layer PCL may include a first conductive layer located between the substrate SUB and the buffer layer BFL, a second conductive layer located between the first gate-insulating layer GI1 and the second gate-insulating layer GI2, a third conductive layer located between the second gate-insulating layer GI2 and the interlayer insulating layer ILD, a fourth conductive layer located between the interlayer insulating layer ILD and the first via layer VIA1, a fifth conductive layer located between the first passivation layer PAS1 and the second via layer VIA2, and a sixth conductive layer located between the second passivation layer PAS2 and the third via layer VIA3.

The first conductive layer may be formed of a single layer made of one or a mixture thereof selected from the group consisting of copper (Cu), molybdenum (Mo), tungsten (W), neodymium (Nd), titanium (Ti), aluminum (Al), silver (Ag), and/or an alloy thereof. Alternatively, the first conductive layer may be formed in a double-layer or multi-layer structure made of a low-resistance material, such as molybdenum (Mo), titanium (Ti), copper (Cu), aluminum (Al), or silver (Ag) to reduce line resistance. Each of the second to sixth conductive layers may include a same material as the first conductive layer or include one or more suitable materials selected from materials disclosed as a material constituting the first conductive layer, but the disclosure is not limited thereto.

The pixel circuit layer PCL may include the pixel circuit PXC and a plurality of electrodes and lines electrically connected to the pixel circuit PXC. For example, the pixel circuit layer PCL may include a lower metal pattern BML, the transistor T, the storage capacitor Cst, a connection electrode CCE, an anode connection line ACL, and a bridge pattern BRP. However, the disclosure is not limited thereto.

The lower metal pattern BML may absorb or block light incident to the pixel circuit PXC from the second surface SF2 of the substrate SUB. The lower metal pattern BML may be the first conductive layer located between the substrate SUB and the buffer layer BFL. According to one or more embodiments, the lower metal pattern BML may be electrically connected to the transistor T. In this case, a driving range of a voltage (e.g., predetermined voltage) supplied to a gate electrode GE of the transistor T may be widened. In case that the lower metal pattern BML is electrically connected to the transistor T, a channel region CHA of the transistor T may be stabilized. As the lower metal pattern BML is electrically connected to the transistor T, floating of the lower metal pattern BML may be reduced or prevented.

The transistor T may include a semiconductor pattern and the gate electrode GE overlapping one region of the semiconductor pattern. The transistor T may be, for example, the first transistor T1 described with reference to FIG. 3.

The semiconductor pattern may be located on/above the buffer layer BFL. The semiconductor pattern may include the channel region CHA, a first terminal TE1, and a second terminal TE2. The first terminal TE1 and the second terminal TE2 may be changed into conductors by heat-treating the semiconductor pattern (or by doping the semiconductor pattern with high-concentration impurities). For example, the semiconductor pattern may include polycrystalline silicon, single crystal silicon, low-temperature polycrystalline silicon, amorphous silicon, or an oxide semiconductor. As another example, the semiconductor pattern may include first and second active layers located on different layers. In this case, the first active layer may include polycrystalline silicon, single crystal silicon, low-temperature polycrystalline silicon, or amorphous silicon, and the second active layer may include an oxide semiconductor.

The gate electrode GE may be located on/above the first gate-insulating layer GI1. The gate electrode GE may be the second conductive layer located between the first gate-insulating layer GI1 and the second gate-insulating layer GI2. The gate electrode GE may overlap the channel region CHA of the semiconductor pattern. The first gate-insulating layer GI1 located between the semiconductor pattern and the gate electrode GE may insulate the channel region CHA of the semiconductor pattern from the gate electrode GE.

The second conductive layer may include a lower electrode LE of the storage capacitor Cst.

According to one or more embodiments, the lower electrode LE may be electrically connected to the gate electrode GE of the transistor T.

The second conductive layer including the gate electrode GE and the lower electrode LE may be composed of a single layer or multiple layers. The second gate-insulating layer GI2 may be located on/above the second conductive layer described above.

An upper electrode UE of the storage capacitor Cst may be located on/above the second gate-insulating layer GI2. The upper electrode UE may be the third conductive layer positioned between the second gate-insulating layer GI2 and the interlayer insulating layer ILD. The upper electrode UE may overlap the lower electrode LE with the second gate-insulating layer GI2 interposed therebetween to form capacitance. In case that an overlapping area of the lower electrode LE and the upper electrode UE is large, the capacitance of the storage capacitor Cst may increase. The third conductive layer including the upper electrode UE may be composed of a single layer or multiple layers.

The interlayer insulating layer ILD may be located on/above the upper electrode UE.

The connection electrode CCE may be located on/above the interlayer insulating layer ILD. The connection electrode CCE may be the fourth conductive layer positioned between the interlayer insulating layer ILD and the first via layer VIA1. The connection electrode CCE may be connected to the second terminal TE2 of the transistor T through contact holes penetrating the interlayer insulating layer ILD, the second gate-insulating layer GI2, and the first gate-insulating layer GI1. The fourth conductive layer including the connection electrode CCE may be composed of a single layer or multiple layers.

The first via layer VIA1 may be located on/above the fourth conductive layer. The first via layer VIA1 may planarize an upper surface of the fourth conductive layer.

The first passivation layer PAS1 may be located on/above the first via layer VIA1.

The anode connection line ACL may be located on/above the first passivation layer PAS1. The anode connection line ACL may be the fifth conductive layer positioned between the first passivation layer PAS1 and the second via layer VIA2.

The anode connection line ACL may be electrically connected to the connection electrode CCE through contact holes penetrating the first passivation layer PAS1 and the first via layer VIA1. The anode connection line ACL may be electrically connected to the second terminal TE2 of the transistor T through the connection electrode CCE.

The fifth conductive layer including the anode connection line ACL may be composed of a single layer or multiple layers.

The second via layer VIA2 may be located on/above the fifth conductive layer. The second via layer VIA2 may planarize an upper surface of the fifth conductive layer.

The second passivation layer PAS2 may be located on/above the second via layer VIA2.

The bridge pattern BRP may be located on/above the second passivation layer PAS2. The bridge pattern BRP may be the sixth conductive layer positioned between the second passivation layer PAS2 and the third via layer VIA3. The bridge pattern BRP may be electrically connected to the anode connection line ACL through contact holes penetrating the second passivation layer PAS2 and the second via layer VIA2. The bridge pattern BRP may be electrically connected to the transistor T through the anode connection line ACL and the connection electrode CCE. The sixth conductive layer including the bridge pattern BRP may be composed of a single layer or multiple layers.

The pixel circuit layer PCL may include the first power source line PL1 (refer to FIG. 3) to which the voltage of the first driving power source VDD is applied and the second power source line PL2 (refer to FIG. 3) to which the voltage of the second driving power source VSS is applied. For example, the first power source line PL1 and the second power source line PL2 may be located on/above the same layer as the bridge pattern BRP. For example, the first power source line PL1 and the second power source line PL2 may be the sixth conductive layer located on/above the second passivation layer PAS2.

The third via layer VIA3 may be entirely located on/above the sixth conductive layer. The third via layer VIA3 may planarize an upper surface of the sixth conductive layer. In one or more embodiments, the third via layer VIA3 may include the first contact hole CH1 exposing a portion of the bridge pattern BRP. In addition, the third via layer VIA3 may be partially opened to include the second contact hole CH2. For example, the third via layer VIA3 may include the second contact hole CH2 exposing a portion of the second power source line PL2.

A seventh conductive layer may be located on/above the pixel circuit layer PCL having the configuration described above. The seventh conductive layer may include the first electrode EL1, the second electrode EL2, the third electrode EL3, the fourth electrode EL4, and the common line COL located on/above the third via layer VIA3 of the pixel circuit layer PCL. The seventh conductive layer may include a suitable material selected from materials disclosed as a material constituting the first conductive layer, and may be composed of a single layer or multiple layers.

The first electrode EL1, the second electrode EL2, the third electrode EL3, and the fourth electrode EL4 may be spaced apart from each other on the third via layer VIA3. In one or more embodiments, the first electrode EL1 and the third electrode EL3 may be integrally formed to be electrically connected to each other. The second electrode EL2 and the fourth electrode EL4 may be branched from the common line COL. The second electrode EL2, the fourth electrode EL4, and the common line COL may be integrally formed to be electrically connected to each other.

The third electrode EL3 may be electrically connected to some component of the pixel circuit layer PCL, for example, the transistor T, through the first contact hole CH1 of the third via layer VIA3. The common line COL may be electrically connected to some component of the pixel circuit layer PCL, for example, the second power source line PL2 through the second contact hole CH2 of the third via layer VIA3.

In one or more embodiments, the first electrode EL1 may include four first sub-electrodes, and the second electrode EL2 may include four second sub-electrodes. For example, the first electrode EL1 may include the (1-1)th sub-electrode SUE1_1, the (1-2)th sub-electrode SUE1_2, the (1-3)th sub-electrode SUE1_3, and the (1-4)th sub-electrode SUE1_4. The second electrode EL2 may include the (2-1)th sub-electrode SUE2_1, the (2-2)th sub-electrode SUE2_2, the (2-3)th sub-electrode SUE2_3, and the (2-4)th sub-electrode SUE2_4.

In the above-described embodiment(s), the first electrode EL1 (or first sub-electrodes) may be the anode electrically connected to the first end EP1 of the light-emitting element LD (refer to FIG. 3), and the second electrode EL2 (or second sub-electrodes) may be the cathode electrically connected to the second end EP2 of the light-emitting element LD. According to one or more embodiments, each of the first electrode EL1 and the second electrode EL2 may be a bonding electrode bonded (coupled) to the light-emitting element LD. Each of the first electrode EL1 and the second electrode EL2 may be bonded to the bonding electrode of the light-emitting element LD to electrically connect the light-emitting element LD and the pixel circuit PXC.

The first electrode EL1, the second electrode EL2, the third electrode EL3, the fourth electrode EL4, the common line COL, the first dummy electrode DME1, and the second dummy electrode DME2 may be formed by a same process, positioned at a same layer, and include a same material.

The seventh conductive layer including the first electrode EL1, the second electrode EL2, the third electrode EL3, the fourth electrode EL4, the common line COL, the first dummy electrode DME1, and the second dummy electrode DME2 may be located on the third via layer VIA3, and may be composed of a conductive material having a reflectance (e.g., predetermined reflectance) so that light emitted from the light-emitting element LD proceeds in an image display direction (or front direction) of the display device DD (refer to FIG. 1). The conductive material may include an opaque metal suitable (or advantageous) for reflecting light emitted from the light-emitting element LD in the image display direction (or a desired direction) of the display device DD. The opaque metal may include, for example, silver (Ag), magnesium (Mg), aluminum (Al), platinum (Pt), palladium (Pd), gold (Au), nickel (Ni), neodymium (Nd), iridium (Ir), chromium (Cr), titanium (Ti), or an alloy thereof. According to one or more embodiments, the seventh conductive layer may include a transparent conductive material. The transparent conductive material may include a conductive oxide, such as indium tin oxide (ITO), indium zinc oxide (IZO), zinc oxide (ZnO), indium gallium zinc oxide (IGZO), and indium tin zinc oxide (ITZO), a conductive polymer, such as poly(3,4-ethylenedioxythiophene) (PEDOT), or the like. In case that the seventh conductive layer includes a transparent conductive material, a separate conductive layer made of an opaque metal may be further included to reflect light emitted from the light-emitting element LD in the image display direction of the display device DD. However, the material of the seventh conductive layer is not limited to the materials described above.

The seventh conductive layer may be provided and/or formed as a single layer, but the disclosure is not limited thereto. According to one or more embodiments, the seventh conductive layer may be provided and/or formed as a multi-layer structure in which at least two materials of metals, alloys, conductive oxides, and/or conductive polymers are stacked. The seventh conductive layer may be formed of multiple layers including at least a double layer.

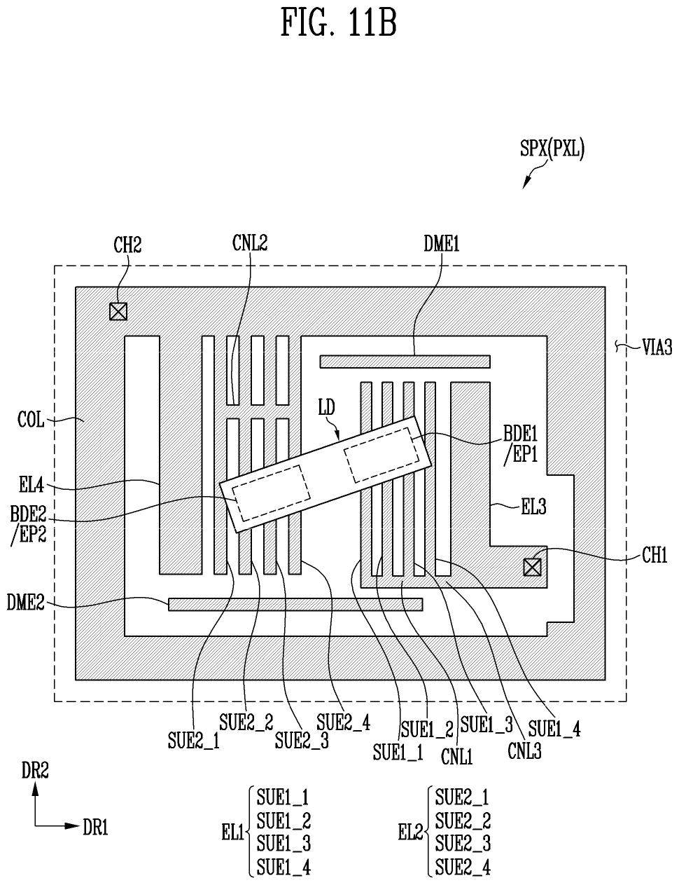

A detailed description of the sub-pixel SPX (or pixel PXL) including the light-emitting element LD bonded to the first and second electrodes EL1 and EL2 will be described later with reference to FIGS. 11A to 13.

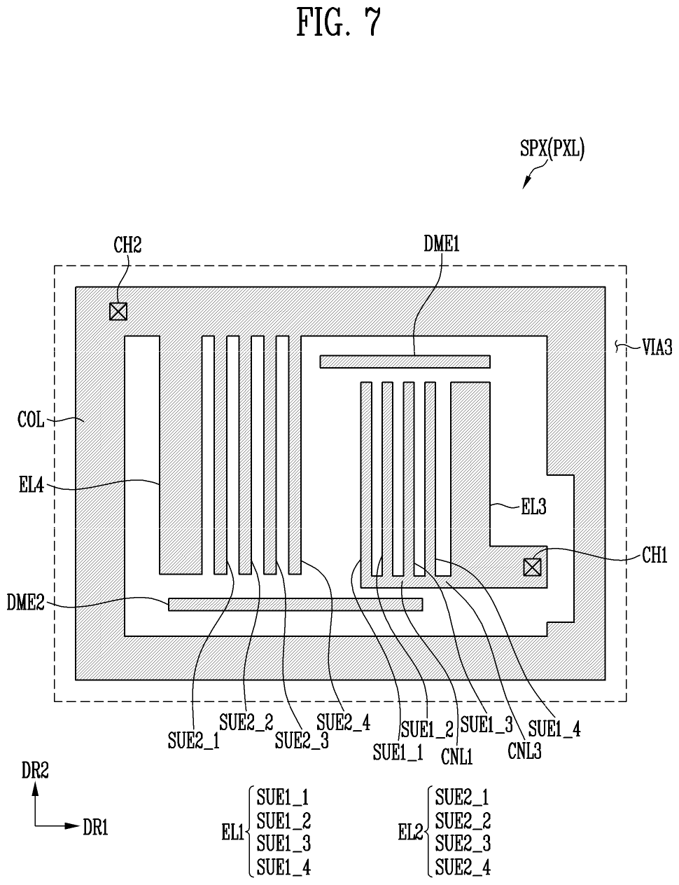

FIGS. 6 to 10 are schematic plan views illustrating sub-pixels SPX according to embodiments.

Regarding the shapes of the first and second electrodes EL1 and EL2, FIGS. 6 to 10 show modified examples of the one or more embodiments corresponding to FIG. 4.

Regarding the embodiments of FIGS. 6 to 10, to avoid overlapping descriptions, differences from the above-described embodiments will be mainly described.

Referring to FIG. 6, the sub-pixel SPX (or pixel PXL) may include the first electrode EL1, the second electrode EL2, the third electrode EL3, and the fourth electrode EL4 spaced apart from each other on the third via layer VIA3. Also, the sub-pixel SPX may include the common line COL, the first dummy electrode DME1, and the second dummy electrode DME2.

The first electrode EL1 may include the (1-1)th sub-electrode SUE1_1, the (1-2)th sub-electrode SUE1_2, the (1-3)th sub-electrode SUE1_3, and the (1-4)th sub-electrode SUE1_4. The (1-1)th sub-electrode SUE1_1, the (1-2)th sub-electrode SUE1_2, the (1-3)th sub-electrode SUE1_3, and the (1-4)th sub-electrode SUE1_4 may be arranged along the direction DR1, and may be electrically connected to each other through the first connection line CNL1. The (1-1)th sub-electrode SUE1_1, the (1-2)th sub-electrode SUE1_2, the (1-3)th sub-electrode SUE1_3, and the (1-4)th sub-electrode SUE1_4 may be arranged along the first direction DR1, and may be electrically connected to each other through the fourth connection line CNL4. The first connection line CNL1 may be positioned at one end (for example, an end adjacent to the second dummy electrode DME2) of each of the (1-1)th sub-electrode SUE1_1, the (1-2)th sub-electrode SUE1_2, the (1-3)th sub-electrode SUE1_3, and the (1-4)th sub-electrode SUE1_2. The fourth connection line CNL4 may be positioned at a central region in a direction in which each of the (1-1)th sub-electrode SUE1_1, the (1-2)th sub-electrode SUE1_2, the (1-3)th sub-electrode SUE1_3, and the (1-4)th sub-electrode SUE1_4 extend. Positions of the first and fourth connection lines CNL1 and CNL4 are not limited to the above.

The first electrode EL1 including the (1-1)th sub-electrode SUE1_1, the (1-2)th sub-electrode SUE1_2, the (1-3)th sub-electrode SUE1_3, and the (1-4)th sub-electrodes SUE1_4 electrically connected to each other through the first and fourth connection lines CNL1 and CNL4 may have a mesh shape in a plan view. In the first electrode EL1 including the (1-1)th sub-electrode SUE1_1, the (1-2)th sub-electrode SUE1_2, the (1-3)th sub-electrode SUE1_3, and the (1-4)th sub-electrode SUE1_4 connected to each other through the first and fourth connection lines CNL1 and CNL4, even if a short circuit defect or the like occurs in some of the first sub-electrodes, a signal (e.g., predetermined signal) may be supplied to the first end EP1 of the light-emitting element LD (refer to FIG. 3) through the remaining first sub-electrodes.

The second electrode EL2 may include the (2-1)th sub-electrode SUE2_1, the (2-2)th sub-electrode SUE2_2, the (2-3)th sub-electrode SUE2_3, and the (2-4)th sub-electrode SUE2_4. The (2-1)th sub-electrode SUE2_1, the (2-2)th sub-electrode SUE2_2, the (2-3)th sub-electrode SUE2_3, and the (2-4)-th sub-electrode SUE2_4 may be arranged along the direction DR1, and may be electrically connected to each other through the second connection line CNL2. The (2-1)th sub-electrode SUE2_1, the (2-2)th sub-electrode SUE2_2, the (2-3)th sub-electrode SUE2_3, and the (2-4)th sub-electrode SUE2_4 may be arranged along the first direction DR1, and may be electrically connected to each other through a fifth connection line CNL5.

The second electrode EL2 including the (2-1)th sub-electrode SUE2_1, the (2-2)th sub-electrode SUE2_2, the (2-3)th sub-electrode SUE2_3, and the (2-4)th sub-electrode SUE2_4 electrically connected to each other through the second and fifth connection lines CNL2 and CNL5 may have a mesh shape in a plan view. In the second electrode EL2 including the (2-1)th sub-electrode SUE2_1, the (2-2)th sub-electrode SUE2_2, the (2-3)th sub-electrode SUE2_3, and the (2-4)th sub-electrode SUE2_4 connected to each other through the second and fifth connection lines CNL2 and CNL5, even if a short circuit defect or the like occurs in some of the second sub-electrodes, a signal (e.g., predetermined signal) may be supplied to the second end EP2 of the light-emitting element LD through the remaining second sub-electrodes.

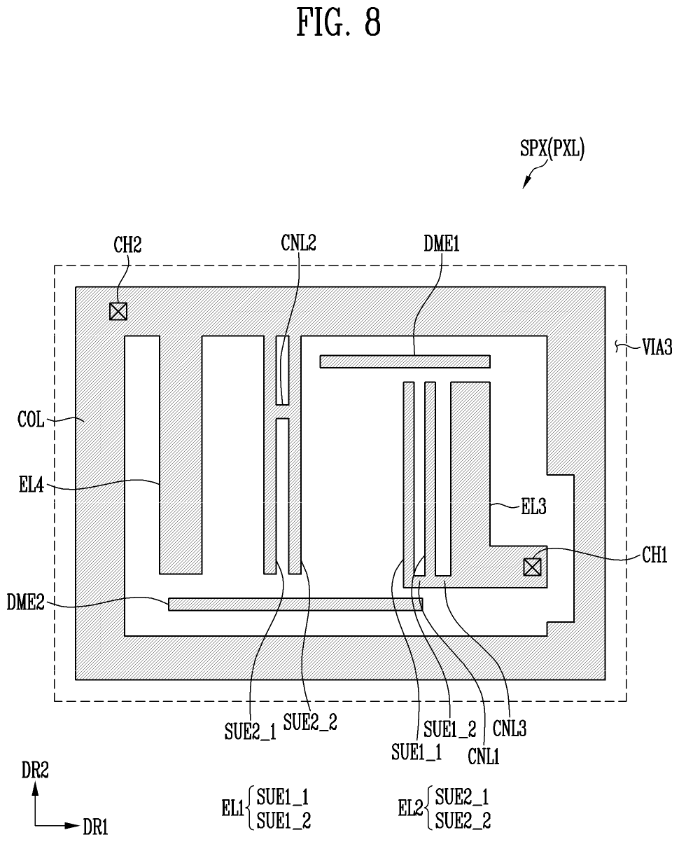

According to one or more embodiments, as shown in FIG. 7, the four second sub-electrodes included in the second electrode EL2 may be electrically connected to each other without a separate connection line extending in the first direction DR1. Each of the four second sub-electrodes may be integrally formed with the common line COL, and may be branched from the common line COL in the second direction DR2. In this case, the four second sub-electrodes may be one region of the common line COL.

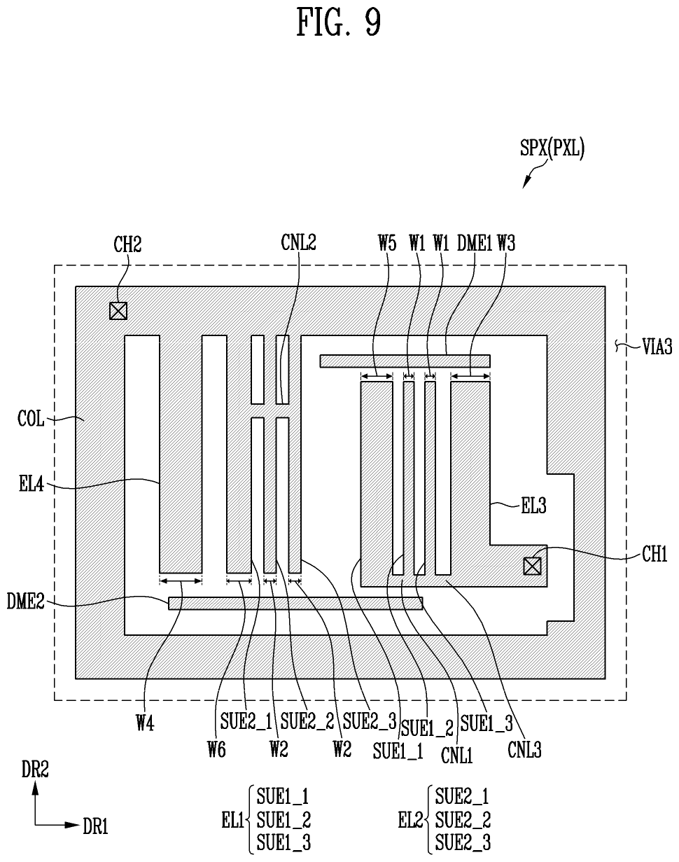

According to one or more embodiments, as shown in FIG. 8, the first electrode EL1 may include two first sub-electrodes spaced apart from each other. For example, the first electrode EL1 may include the (1-1)th sub-electrode SUE1_1 and the (1-2)th sub-electrode SUE1_2 spaced apart from each other. The first connection line CNL1 may be positioned between the (1-1)th sub-electrode SUE1_1 and the (1-2)th sub-electrode SUE1_2, and the (1-1)th sub-electrode SUE1_1 and the (1-2)th sub-electrode SUE1_2 may be electrically connected to each other through the first connection line CNL1. The (1-1)th sub-electrode SUE1_1, the (1-2)th sub-electrode SUE1_2, and the first connection line CNL1 may be integrally formed. In this case, the first connection line CNL1 may be regarded as one region of the (1-1)th sub-electrode SUE1_1 or one region of the (1-2)th sub-electrode SUE1_2. In one or more embodiments, the (1-1)th sub-electrode SUE1_1 and the (1-2)th sub-electrode SUE1_2 may have the same width in the first direction DR1, but the disclosure is not limited thereto.

Similarly, as shown in FIG. 8, the second electrode EL2 may include two second sub-electrodes spaced apart from each other. For example, the second electrode EL2 may include the (2-1)th sub-electrode SUE2_1 and the (2-2)-th sub-electrode SUE2_2 spaced apart from each other. The second connection line CNL2 may be positioned between the (2-1)th sub-electrode SUE2_1 and the (2-2)th sub-electrode SUE2_2. The (2-1)th sub-electrode SUE2_1 and the (2-2)th sub-electrode SUE2_2 may be electrically connected to each other through the second connection line CNL2. The (2-1)th sub-electrode SUE2_1, the (2-2)th sub-electrode SUE2_2, and the second connection line CNL2 may be integrally formed. In this case, the second connection line CNL2 may be regarded as one region of the (2-1)th sub-electrode SUE2_1 or one region of the (2-2)th sub-electrode SUE2_2. In one or more embodiments, the (2-1)th sub-electrode SUE2_1 and the (2-2)-th sub-electrode SUE2_2 may have the same width in the first direction DR1, but the disclosure is not limited thereto.

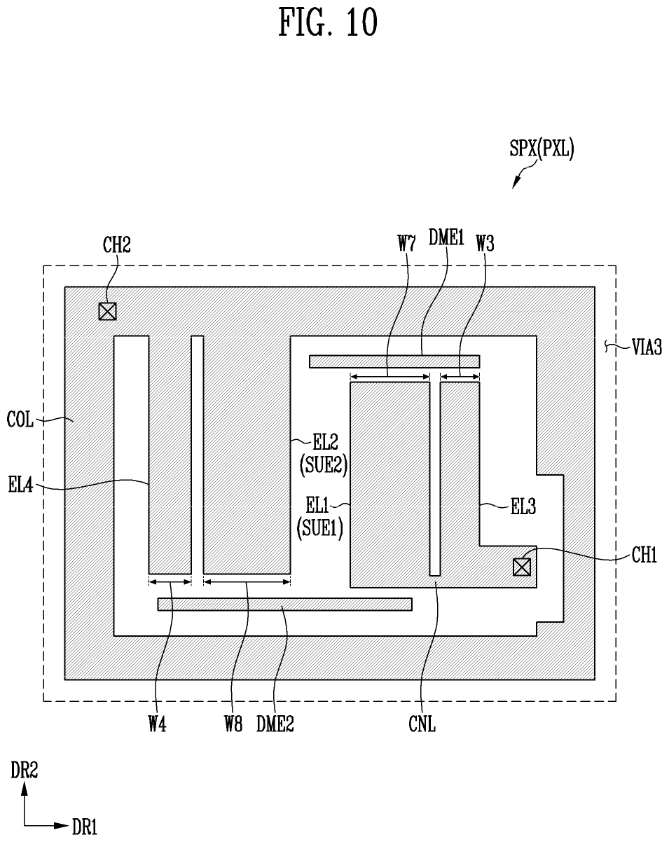

The first electrode EL1 may include a plurality of first sub-electrodes in which at least one first sub-electrode has a different width than the rest of the first sub-electrodes. For example, as shown in FIG. 9, the first electrode EL1 may include the (1-1)th sub-electrode SUE1_1, the (1-2)th sub-electrode SUE1_2, and the (1-3)th sub-electrode SUE1_3, and a width W5 (for example, a width in the first direction DR1) of the (1-1)th sub-electrode SUE1_1 may be greater than the widths W1 of the (1-2)th and (1-3)th sub-electrodes SUE1_2 and SUE1_3. The width W5 of the (1-1)th sub-electrode SUE1_1 may be less than the width W3 of the third electrode EL3, but the disclosure is not limited thereto. According to one or more embodiments, the width W5 of the (1-1)th sub-electrode SUE1_1 may be equal to or greater than the width W3 of the third electrode EL3. According to one or more other embodiments, the width W5 of the (1-1)th sub-electrode SUE1_1 may be less than the widths W1 of the (1-2)th and (1-3)th sub-electrodes SUE1_2 and SUE1_3. In addition, among the (1-1)th sub-electrode SUE1_1, the (1-2)th sub-electrode SUE1_2, and the (1-3)th sub-electrode SUE1_3, the (1-2)th sub-electrode SUE1_2 or the (1-3)th sub-electrode SUE1_3 may have a larger width than the rest of the first sub-electrodes.

The second electrode EL2 may include a plurality of second sub-electrodes in which at least one second sub-electrode has a different width than the rest of the second sub-electrodes. For example, as shown in FIG. 9, the second electrode EL2 may include the (2-1)th sub-electrode SUE2_1, the (2-2)th sub-electrode SUE2_2, and the (2-3)-th sub-electrode SUE2_3, and a width W6 (for example, a width in the first direction DR1) of the (2-1)th sub-electrode SUE2_1 may be greater than the widths W2 of the (2-2)th and (2-3)th sub-electrodes SUE2_2 and SUE2_3. The width W6 of the (2-1)th sub-electrode SUE2_1 may be less than the width W4 of the fourth electrode EL4, but the disclosure is not limited thereto. According to one or more embodiments, the width W6 of the (2-1)th sub-electrode SUE2_1 may be equal to or greater than the width W4 of the fourth electrode EL4. According to one or more other embodiments, the width W6 of the (2-1)th sub-electrode SUE2_1 may be less than the widths W2 of the (2-2)th and (2-3)th sub-electrodes SUE2_2 and SUE2_3. Among the (2-1)th sub-electrode SUE2_1, the (2-2)th sub-electrode SUE2_2, and the (2-3)-th sub-electrode SUE2_3, the (2-2)th sub-electrode SUE2_2 or the (2-3)th sub-electrode SUE2_3 may have a larger width than the rest of the second sub-electrodes.

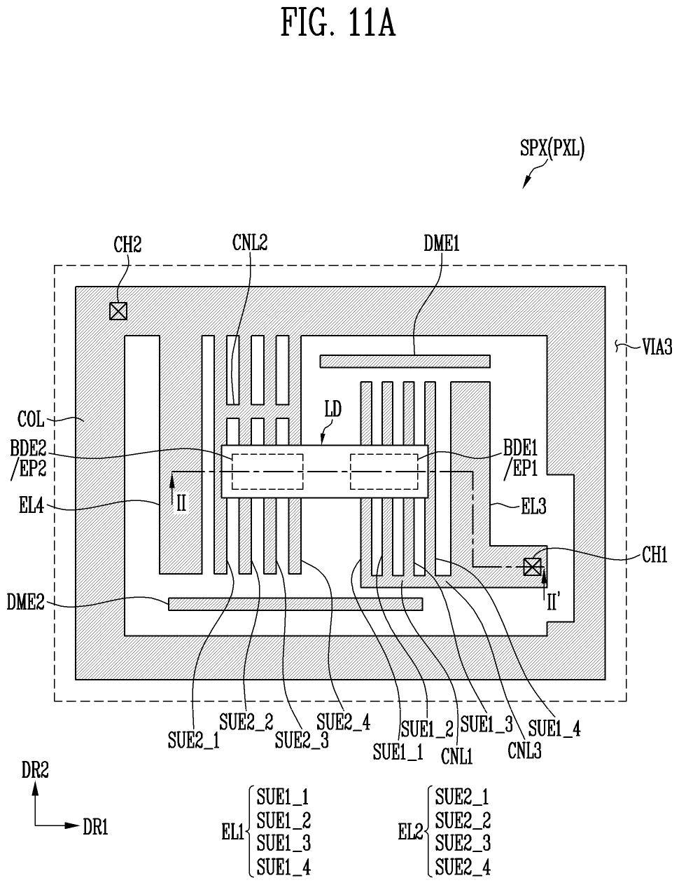

Although one or more embodiments in which the first electrode EL1 includes the plurality of first sub-electrodes and the second electrode EL2 includes the plurality of second sub-electrodes has been described, the disclosure is not limited thereto. According to one or more embodiments, as shown in FIG. 10, the first electrode EL1 may be composed of one first sub-electrode SUE1, and the second electrode EL2 may be composed of one second sub-electrode SUE2. The first electrode EL1 (or first sub-electrode SUE1) may be electrically connected to the third electrode EL3 through a connection line CNL, and the second electrode EL2 (or second sub-electrode SUE2) may be branched from the common line COL in the second direction DR2 together with the fourth electrode EL4. A width W7 (for example, a width in the first direction DR1) of the first electrode EL1 (or first sub-electrode SUE1) may be greater than the width W3 of the third electrode EL3, but the disclosure is not limited thereto. A width W8 (for example, a width in the first direction DR1) of the second electrode EL2 (or second sub-electrode SUE2) may be greater than the width W4 of the fourth electrode EL4, but the disclosure is not limited thereto.

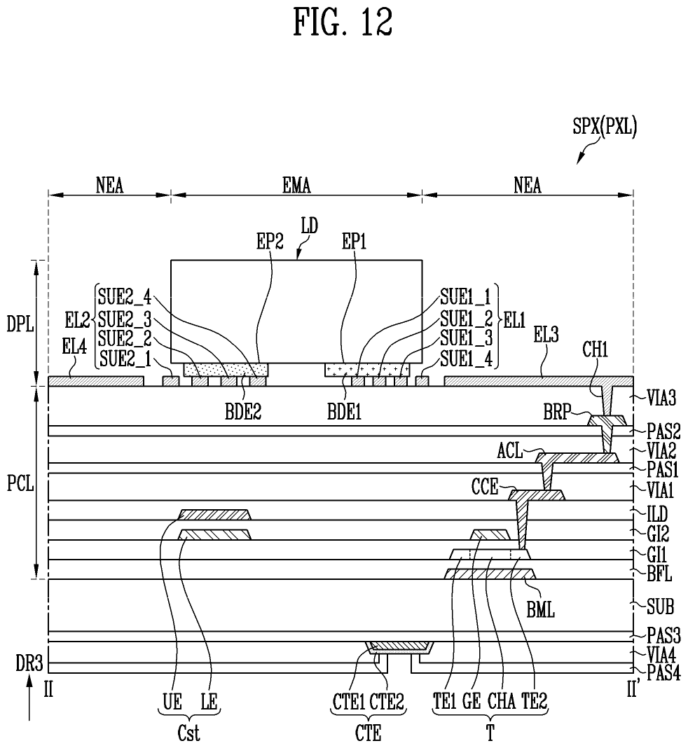

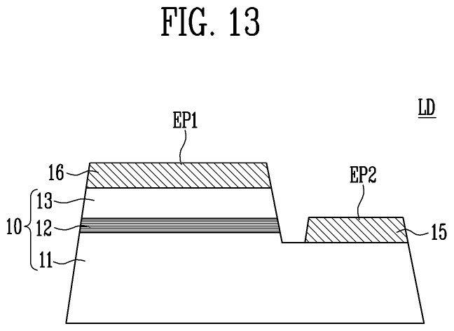

FIGS. 11A and 11B are schematic plan views illustrating a state in which a light-emitting element LD is transferred in the sub-pixel SPX of FIG. 4. FIG. 12 is a schematic cross-sectional view taken along the line II˜II′ in FIG. 11A. FIG. 13 is a schematic cross-sectional view of a light-emitting element LD of FIG. 12.

The embodiments of FIGS. 11A and 11B show different embodiments in relation to the aligned positions of the light-emitting elements LD. For example, FIG. 11A shows one or more embodiments in which the light-emitting element LD is aligned in a direction parallel to the first direction DR1 between the first electrode EL1 and the second electrode EL2, and FIG. 11B shows one or more embodiments in which the light-emitting element LD is aligned in a direction inclined to the first direction DR1 (or the second direction DR2) between the first electrode EL1 and the second electrode EL2.

Regarding the embodiments of FIGS. 11A to 13, to avoid overlapping descriptions, differences from the above-described embodiments will be mainly described.

Referring to FIGS. 11A to 13, the sub-pixel SPX (or pixel PXL) may include the substrate SUB, the pixel circuit layer PCL, and the display element layer DPL.

The display element layer DPL may include electrodes, the common line COL, dummy electrodes, and the light-emitting element LD.

The electrodes may include the first electrode EL1, the second electrode EL2, the third electrode EL3, and the fourth electrode EL4 spaced apart from each other on the third via layer VIA3 of the pixel circuit layer PCL. The first electrode EL1 and the third electrode EL3 may be electrically connected to each other through the third connection line CNL3. The second electrode EL2 and the fourth electrode EL4 may be branched from the common line COL in the second direction DR2, and may be electrically connected to each other. The first electrode EL1 may include the (1-1)th to (1-4)th sub-electrodes SUE1_1, SUE1_2, SUE1_3, and SUE1_4. The second electrode EL2 may include the (2-1)th to (2-4)th sub-electrodes SUE2_1, SUE2_2, SUE2_3, and SUE2_4.

The common line COL may be provided in a form surrounding the first to fourth electrodes EL1, EL2, EL3, and EL4 in a plan view, and may be electrically connected to the second driving power source VSS described with reference to FIG. 3 through the second contact hole CH2 penetrating the third via layer VIA3.

The dummy electrode may include a first dummy electrode DME1 and a second dummy electrode DME2 spaced apart from the common line COL and the electrodes. The first and second dummy electrodes DME1 and DME2 may be positioned on the third via layer VIA3, and may be electrically insulated from the first to the fourth electrodes and the common line COL, unless the light-emitting element LD is connected in a reverse direction between the electrodes and the repair process is required.

The light-emitting element LD may be bonded to the first and second electrodes EL1 and EL2, respectively. As shown in FIG. 13, the light-emitting element LD may include a semiconductor structure 10, a first contact electrode 15, and a second contact electrode 16. The semiconductor structure 10 may be formed by mesa etching a first semiconductor layer 11, an active layer 12, and a second semiconductor layer 13 after sequentially forming the first semiconductor layer 11, the active layer 12, and the second semiconductor layer 13. The light-emitting element LD having a package shape may be formed by sequentially forming the first contact electrode 15 and the second contact electrode 16 on the semiconductor structure 10, but the disclosure is not limited thereto.

In the light-emitting element LD, a length in a vertical direction, a length in a horizontal direction, and a length in a thickness direction of the substrate SUB may be several to hundreds of μm, respectively.

The light-emitting element LD may be formed by growing on a semiconductor substrate, such as a silicon wafer. The light-emitting element LD may be directly transferred onto the first electrode EL1 and the second electrode EL2 of the display element layer DPL on the silicon wafer. Alternatively, the light-emitting element LD may be transferred onto the first electrode EL1 and the second electrode EL2 of the display element layer DPL through an electrostatic method using an electrostatic head or a stamp method using an elastic polymer material, such as PDMS or silicon as a transfer substrate.

In one or more embodiments, the light-emitting element LD may include the first end EP1 contacting the first electrode EL1 (or first sub-electrode), and the second end EP2 contacting the second electrode EL2 (or second sub-electrode). The light-emitting element LD may be a light-emitting element (or light-emitting diode) having a horizontal structure in which the first end EP1 and the second end EP2 are located on the same plane. The second contact electrode 16 electrically connected to the second semiconductor layer 13 may be positioned at the first end EP1, and the first contact electrode 15 electrically connected to the first semiconductor layer 11 may be positioned at the second end EP2.

The semiconductor structure 10 may emit light by recombination of electrons and holes according to a current flowing between the first contact electrode 15 and the second contact electrode 16. The semiconductor structure 10 may include the first semiconductor layer 11, the active layer 12, and the second semiconductor layer 13.

The first semiconductor layer 11 may include, for example, at least one n-type semiconductor layer. For example, the first semiconductor layer 11 may be an n-type semiconductor layer including at least one semiconductor material of InAlGaN, GaN, AlGaN, InGaN, AlN, and/or InN, and doped with a first conductive dopant (or an n-type dopant), such as Si, Ge, Sn, or the like. However, the material constituting the first semiconductor layer 11 is not limited thereto, and the first semiconductor layer 11 may be formed of various other materials. In one or more embodiments, the first semiconductor layer 11 may include a gallium nitride (GaN) semiconductor material doped with the first conductive dopant (or n-type dopant).

The active layer 12 (or light-emitting layer) may be located on a portion of one surface of the first semiconductor layer 11. The active layer 12 may include a material having a single or multi-quantum well structure. In case that the active layer 12 includes a material having a multi-quantum well structure, the active layer 12 may have a structure in which a plurality of well layers and barrier layers are alternately stacked. In this case, the well layer may be formed of InGaN, and the barrier layer may be formed of GaN or AlGaN, but the disclosure is not limited thereto. Alternatively, the active layer 12 may have a structure in which a semiconductor material having a high band gap energy and a semiconductor material having a low band gap energy are alternately stacked, and may include group 3 to group 5 semiconductor materials according to the wavelength range of emitted light. The active layer 12 may include a first surface in contact with the first semiconductor layer 11 and a second surface in contact with the second semiconductor layer 13.

The second semiconductor layer 13 may be located on one surface of the active layer 12, and may provide holes to the active layer 12. The second semiconductor layer 13 may include a semiconductor layer of a different type from the first semiconductor layer 11. For example, the second semiconductor layer 13 may include at least one p-type semiconductor layer. For example, the second semiconductor layer 13 may include a p-type semiconductor layer including at least one semiconductor material of InAlGaN, GaN, AlGaN, InGaN, AlN, and/or InN, and doped with a second conductive dopant (or a p-type dopant), such as Mg, Zn, Ca, Se, Ba, or the like. However, the material constituting the second semiconductor layer 13 is not limited thereto, and the second semiconductor layer 13 may be formed of various other materials. In one or more embodiments, the second semiconductor layer 13 may include a gallium nitride (GaN) semiconductor material doped with the second conductive dopant (or p-type dopant).

The first semiconductor layer 11, the active layer 12, and the second semiconductor layer 13 may be provided in a sequentially stacked structure on a semiconductor substrate. Here, the semiconductor substrate may include a semiconductor material, such as a sapphire substrate or a silicon substrate. After the semiconductor substrate is used as a growth substrate for growing the first semiconductor layer 11, the active layer 12, and the second semiconductor layer 13, the semiconductor substrate may be separated from the first semiconductor layer 11 through a process of separating a substrate. Here, the process of separating the substrate may be a laser lift-off method, a chemical lift-off method, or the like. As the growth substrate is removed from the semiconductor structure 10, the semiconductor structure 10 may have a thin thickness. The semiconductor structure 10 described above may have a size as small as a micro scale (or micrometer), but the disclosure is not limited thereto.

The first contact electrode 15 may be provided and/or formed on the semiconductor structure 10. For example, the first contact electrode 15 may be provided and/or formed on the first semiconductor layer 11 to be electrically separated from the active layer 12 and the second semiconductor layer 13. The first contact electrode 15 may make ohmic contact with the first semiconductor layer 11. In one or more embodiments, the first contact electrode 15 may be positioned at the second end EP2 (or n-type end) of the light-emitting element LD, and may contact a second bonding electrode BDE2 for bonding.

The second contact electrode 16 may be provided and/or formed on the semiconductor structure 10. For example, the second contact electrode 16 may be provided and/or formed on the second semiconductor layer 13. The second contact electrode 16 may make ohmic contact with the second semiconductor layer 13. In one or more embodiments, the second contact electrode 16 may be positioned at the first end EP1 (or p-type end) of the light-emitting element LD and may contact a first bonding electrode BDE1 for bonding.

The first and second contact electrodes 15 and 16 may include a conductive material. For example, the first and second contact electrodes 15 and 16 may include an opaque metal in which chromium (Cr), titanium (Ti), aluminum (Al), gold (Au), nickel (Ni), and an oxide or alloy thereof are used alone or in combination, but the disclosure is not limited thereto. According to one or more embodiments, the first and second contact electrodes 15 and 16 may include a transparent conductive oxide, such as indium tin oxide (ITO), indium zinc oxide (IZO), zinc oxide (ZnO), indium gallium zinc oxide (IGZO), or indium tin zinc oxide (ITZO). According to one or more embodiments, the first and second contact electrodes 15 and 16 may be solder bumps.

According to one or more embodiments, the light-emitting element LD may further include an insulating film surrounding an outer circumferential surface of the semiconductor structure 10.

The light-emitting element LD may be bonded (coupled) to the first and second electrodes EL1 and EL2 through bonding electrodes. For example, the first end EP1 (or p-type end) of the light-emitting element LD may be bonded to the first electrode EL1 (or first sub-electrodes) through the first bonding electrode BDE1. The second end EP2 (or n-type end) of the light-emitting element LD may be bonded to the second electrode EL2 (or second sub-electrodes) through the second bonding electrode BDE2. Each of the first and second bonding electrodes BDE1 and BDE2 may be selected from a group including gold (Au) and tin (Sn) having suitable bonding strength (or adhesive strength) so as to facilitate generation and growth of an intermetallic compound, but the disclosure is not limited thereto. According to one or more embodiments, the first bonding electrode BDE1 and the second bonding electrode BDE2 may be omitted.

The light-emitting element LD may be located on the third via layer VIA3 so that the first end EP1 (or the first bonding electrode BDE1) of the light-emitting element LD is positioned on the first electrode EL1 and the second end EP2 (or the second bonding electrode BDE2) of the light-emitting element LD is positioned on the second electrode EL2. After the light-emitting element LD transferred to the transfer substrate by a transport mechanism or the like is moved over the first and second electrodes EL1 and EL2, the light-emitting element LD may be re-transferred onto the first and second electrodes EL1 and EL2.

The light-emitting element LD may overlap the first electrode EL1 and the second electrode EL2, and the first end EP1 and the second end EP2 of the light-emitting element LD may be aligned to face each other in a direction parallel to the first direction DR1 between the third electrode EL3 and the fourth electrode EL4, but the disclosure is not limited thereto. According to one or more embodiments, the first end EP1 and the second end EP2 of the light-emitting element LD may be aligned to face each other in a direction inclined to the first direction DR1 (or the second direction DR2) between the third electrode EL3 and the fourth electrode EL4.

In case that the first end EP1 (or p-type end) of the light-emitting element LD is positioned on the first electrode EL1 and the second end EP2 (or n-type end) of the light-emitting element LD is positioned on the second electrode EL2, the light-emitting element LD and corresponding electrodes may be electrically connected to each other by a bonding process using a suitable bonding method. As the bonding method, for example, an anisotropic conductive film (AFC) bonding method, a laser assist bonding (LAB) method, an ultrasonic bonding method, a bump-ball surface mounting (ball grid array, BGA) method, a pressure and heat bonding (thermal compression bonding, TC) method, or the like may be used, but the disclosure is not limited thereto.

In case that the first end EP1 (or p-type end) of the light-emitting element LD is electrically connected to the first electrode EL1, and the second end EP2 (or n-type end) of the light-emitting element LD is electrically connected to the second electrode EL2, the light-emitting element LD may be connected in a forward direction between the first electrode EL1 and the second electrode EL2. In case that it is assumed that a driving current flows from the first power source line PL1 (refer to FIG. 3) to the second power source line PL2 (refer to FIG. 3) by the transistor T, the driving current may flow to the third electrode EL3 and the first electrode EL1 electrically connected to the third electrode EL3 through the first contact hole CH1. Accordingly, the light-emitting element LD may emit light with a luminance corresponding to the driving current.

In one or more embodiments, because the first electrode EL1 contacted and electrically connected to the first end EP1 (or the first bonding electrode BDE1) of the light-emitting element LD includes the plurality of first sub-electrodes, and because the second electrode EL2 contacted and electrically connected to the second end EP2 (or the second bonding electrode BDE2) of the light-emitting element LD includes the plurality of second sub-electrodes, a plurality of current paths through which current flows from the first electrode EL1 to the second electrode EL2 may be provided. Accordingly, even if the first end EP1 of the light-emitting element LD contacts at least some of the first sub-electrodes, and/or the second end EP2 of the light-emitting element LD contacts at least some of the second sub-electrodes, each end of the light-emitting element LD and a corresponding electrode may be stably electrically connected to each other. Accordingly, reliability of the sub-pixel SPX (or display device DD) can be improved.

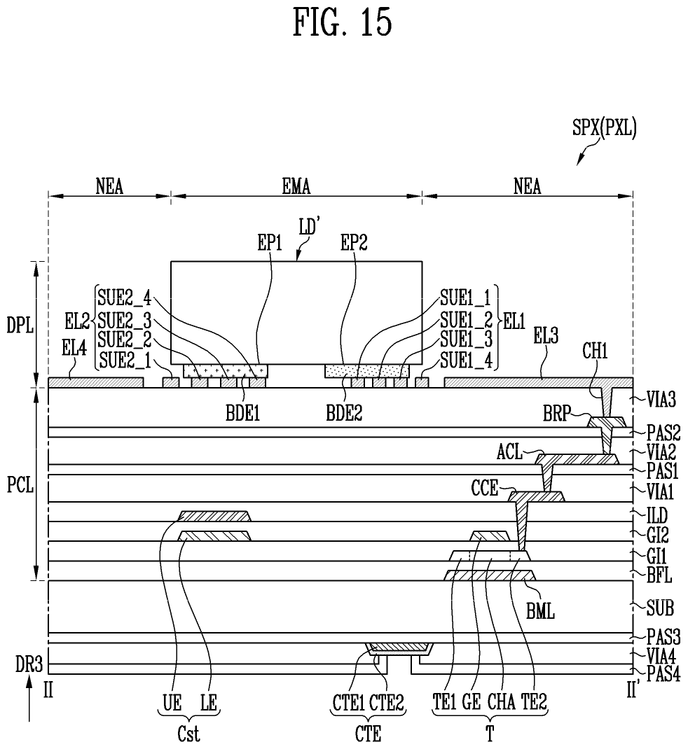

After the light-emitting element LD is transferred onto the first and second electrodes EL1 and EL2, lighting inspection may be performed on the light-emitting element LD. If there is no defect in the light-emitting element LD, the sub-pixel SPX (or display device DD) may be completed. However, if the light-emitting element LD is not lighted in the lighting inspection, and the sub-pixel SPX is visually recognized as a dark spot defect, a repair process may be performed according to the type of defect in the light-emitting element LD. For example, in a process of transferring the light-emitting element LD onto the first and second electrodes EL1 and EL2, the light-emitting element LD may be connected in a reverse direction between the first and second electrodes EL1 and EL2 due to the condition (for example, alignment accuracy) of an equipment or the air flow in the environment within the equipment, and a dark spot defect may occur in the sub-pixel SPX. In this case, the repair process may be performed to change the direction of the current in the sub-pixel SPX to an opposite direction so that the current flows through the light-emitting element LD connected in a reverse direction. A detailed description of a process of repairing the light-emitting element LD connected in a reverse direction will be described later with reference to FIGS. 15 to 17.

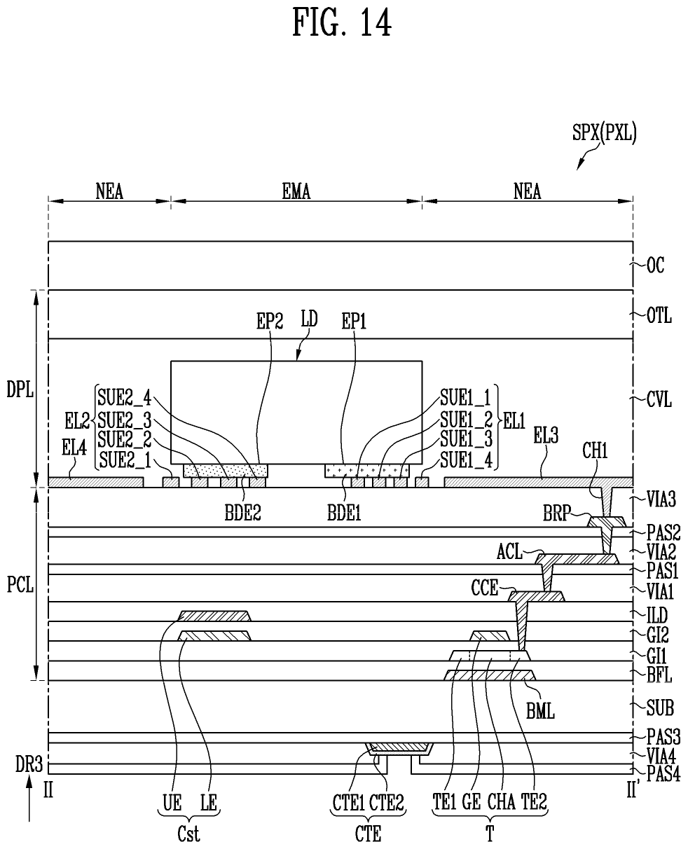

FIG. 14 is a schematic cross-sectional view taken along the line II˜II′ in FIG. 11A and illustrates a sub-pixel SPX according to one or more embodiments.

Regarding the one or more embodiments corresponding to FIG. 14, to avoid overlapping descriptions, differences from the above-described embodiments will be mainly described.

Referring to FIGS. 11A and 14, the sub-pixel SPX may include the substrate SUB, the pixel circuit layer PCL, the display element layer DPL, and an overcoat layer OC.

The display element layer DPL may include the first to fourth electrodes EL1, EL2, EL3, and EL4, the first and second dummy electrodes DME1 and DME2, the common line COL, the light-emitting element LD, the cover layer CVL, and an optical layer OTL.

The cover layer CVL may be located on the seventh conductive layer including the first to fourth electrodes EL1, EL2, EL3, and EL4, the first and second dummy electrodes DME1 and DME2, the common line COL, and the light-emitting element LD to cover the seventh conductive layer and the light-emitting element LD. The cover layer CVL may be an encapsulation substrate or an encapsulation film composed of multiple layers. The cover layer CVL may reduce or prevent oxygen and moisture entering the light-emitting element LD and the pixel circuit layer PCL from the outside. According to one or more embodiments, the cover layer CVL may be a planarization layer that alleviates a step difference caused by components located thereunder.

The optical layer OTL may be located on the cover layer CVL.

The optical layer OTL may convert light emitted from the light-emitting element LD into light having suitable color reproducibility, and may output the light, so that the light output efficiency of each sub-pixel SPX (or each pixel PXL) can be improved. The optical layer OTL may include a color filter layer having a color filter and a light-blocking pattern. According to one or more embodiments, the optical layer OTL may include a color conversion layer including color conversion particles that convert light emitted from the light-emitting element LD into light of a corresponding color (or light having a suitable color reproducibility).

The overcoat layer OC may be located on the optical layer OTL. The overcoat layer OC may cover lower members including the optical layer OTL. The overcoat layer OC may protect the lower members described above from foreign substances, such as dust.

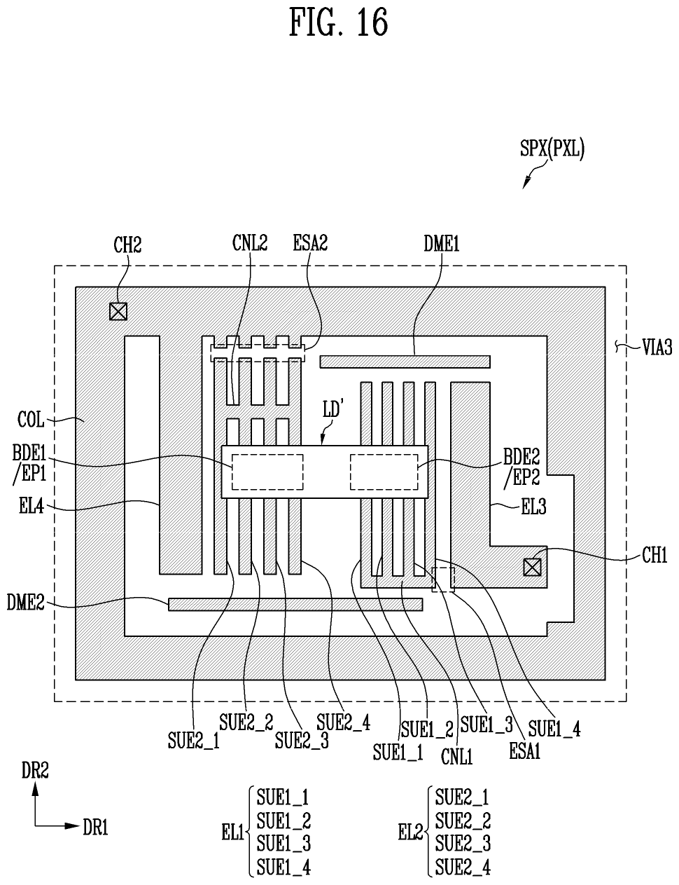

FIG. 15 is a schematic cross-sectional view taken along the line II˜II′ in FIG. 11A, and illustrates a sub-pixel SPX including a defective light-emitting element LD′ in which a defect occurs. FIGS. 16 and 17 are schematic plan views illustrating a method of repairing the defective light-emitting element LD′ of FIG. 15.

Referring to FIGS. 15 to 17, the sub-pixel SPX (or pixel PXL) may include the defective light-emitting element LD′ connected in a reverse direction between the first electrode EL1 and the second electrode EL2.

As described with reference to FIGS. 11A to 13, the defective light-emitting element LD′ may be a reverse light-emitting element having a poor alignment direction because the first end EP1 (or the first bonding electrode BDE1) is contacted and electrically connected to the second electrode EL2, and because the second end EP2 (or the second bonding electrode BDE2) is contacted and electrically connected to the first electrode EL1 in the process of transferring the light-emitting element LD onto the first and second electrodes EL1 and EL2. The defective light-emitting element LD′ may be connected in an opposite direction to the correctly oriented light-emitting element LD between the first electrode EL1 and the second electrode EL2. Accordingly, even if a driving voltage (e.g., predetermined driving voltage, for example, a forward driving voltage) is applied between the first and second electrodes EL1 and EL2, the defective light-emitting element LD′ may be maintained in an inactive state, and thus current may not substantially flow.

The sub-pixel SPX including the defective light-emitting element LD′ may be visually recognized as a dark spot defect, and the repair process may be performed to solve the dark spot defect. The repair process may be performed using a laser. In the repair process, for example, an electrical connection between the first electrode EL1 and the third electrode EL3 and an electrical connection between the second electrode EL2 and the fourth electrode EL4 may be disconnected by using a laser, and then a corresponding electrode and a corresponding dummy electrode may be electrically connected to each other through a laser welding process.

As shown in FIG. 16, in a first electrode separation area ESA1 between the first electrode EL1 (or first sub-electrodes) and the third electrode EL3, the third connection line CNL3 (refer to FIG. 11A) may be removed by using a laser to electrically separate the first electrode EL1 and the third electrode EL3. In addition, in a second electrode separation area ESA2 between the second electrode EL2 (or second sub-electrodes) and the common line COL, a portion of the second electrode EL2 (or each second sub-electrode) may be removed by using a laser to electrically separate the second electrode EL2 and the common line COL. Accordingly, the second electrode EL2 and the fourth electrode EL4 may be electrically separated (or disconnected) from each other.

The third electrode EL3 may be electrically connected to the transistor T through the first contact hole CH1 of the third via layer VIA3, and the fourth electrode EL4 may be electrically connected to the second driving power source VSS (refer to FIG. 3) through the second contact hole CH2 of the third via layer VIA3 and the common line COL. The first electrode EL1 (or first sub-electrodes) electrically separated from the third electrode EL3, and the second electrode EL2 (or second sub-electrodes) electrically separated from the fourth electrode EL4, may be floated.

As described above, after the first and second electrodes EL1 and EL2 are floated by disconnecting the electrical connection between the electrodes using a laser, a process of electrically connecting the first and second dummy electrodes DME1 and DME2 and the first and second electrodes EL1 and EL2 using a laser may be performed. For example, as shown in FIG. 17, the first bridge electrode BRE1 electrically connecting the third electrode EL3 and the second electrode EL2, and the second bridge electrode BRE2 electrically connecting the fourth electrode EL4 and the first electrode EL1, may be formed. The first bridge electrode BRE1 may be formed through a laser welding process so that one end (or first end) of the first dummy electrode DME1 is connected to the second electrode EL2 (for example, the (2-4)th sub-electrode SUE2_4), and so that the other end (or second end) of the first dummy electrode DME1 is connected to the third electrode EL3. The second bridge electrode BRE2 may be formed through a laser welding process so that one end (or a first end) of the second dummy electrode DME2 is connected to the first connection line CNL1 (or first sub-electrodes), and so that the other end (or a second end) of the second dummy electrode DME2 is connected to the fourth electrode EL4.

The second electrode EL2 may be electrically connected to the third electrode EL3 through the first bridge electrode BRE1, and the first electrode EL1 may be electrically connected to the fourth electrode EL4 through the second bridge electrode BRE2. Due to this, the second electrode EL2 may be electrically connected to the transistor T of the pixel circuit layer PCL through the third electrode EL3 and the first contact hole CH1 of the third via layer VIA3, and the first electrode EL1 may be electrically connected to the second driving power source VSS through the fourth electrode EL4 and the second contact hole CH2 of the third via layer VIA3.

Accordingly, current may flow between the second electrode EL2 and the first electrode EL1. For example, the current may flow from the second electrode EL2 toward the first electrode EL1. In this case, the second electrode EL2 may be the anode, and the first electrode EL1 may be the cathode. In this way, a direction of current flowing from the first electrode EL1 to the second electrode EL2 may be changed to a direction of current flowing from the second electrode EL2 to the first electrode EL1 by repairing the sub-pixel SPX in which the dark spot defect has occurred. Therefore, the defective light-emitting element LD′ may be connected in a forward direction between the second electrode EL2 and the first electrode EL1. Accordingly, the reliability of the display device DD can be improved by repairing the sub-pixel SPX in which the dark spot defect has occurred so that the defective light-emitting element LD′ can be driven as a light-emitting element LD that is an effective light source.

In general (e.g., conventionally), if a dark spot defect occurs in the sub-pixel SPX due to the defective light-emitting element LD′ connected in a reverse direction between the first and second electrodes EL1 and EL2, a repair process of removing the defective light-emitting element LD′ with a laser, and re-transferring another light-emitting element LD onto the first and second electrodes EL1 and EL2 may be performed. In this case, a process of removing the defective light-emitting element LD′ and a process of re-transferring another light-emitting element LD onto the first and second electrodes EL1 and EL2 may be added. Therefore, the manufacturing efficiency of the display device DD may decrease, and the light-emitting element LD may be unnecessarily wasted, thereby increasing the manufacturing cost of the display device DD.

In the above-described embodiments, however, after the light-emitting element LD is transferred onto the first electrode EL1 and the second electrode EL2, if the light-emitting element LD is determined to be a defective light-emitting element LD connected in a reverse direction between the first and second electrodes EL1 and EL2, the electrical connection between the first electrode EL1 and the third electrode EL3 and the electrical connection between the second electrode EL2 and the fourth electrode EL4 may be disconnected, and a direction of current flowing from the first electrode EL1 to the second electrode EL2 may be changed to a direction of current flowing from the second electrode EL2 to the first electrode EL1 by forming the first and second bridge electrodes BRE1 and BRE2. Therefore, the sub-pixel SPX in which a dark spot defect has occurred can be suitably repaired. Thus, the otherwise defective light-emitting element LD′ can be driven as a light-emitting element LD that is an effective light source. According to the above-described embodiments, the manufacturing efficiency of the display device DD can be improved, and the manufacturing cost of the display device DD can be reduced by reducing or preventing unnecessary waste of the light-emitting element LD.

According to the display device and the repair method thereof according to the embodiments of the disclosure, even if a dark spot defect occurs in a sub-pixel, the reliability of the display device can be improved by suitably repairing the defective light-emitting element.

According to the embodiments of the disclosure, instead of replacing the defective light-emitting element connected in a reverse direction between the electrodes, the defective light-emitting element may be connected in a forward direction between the electrodes by removing portions of the electrodes using a laser, and by connecting the electrodes to the dummy electrodes (or bridge electrodes) through a laser welding process. Accordingly, unnecessary waste of the light-emitting element can be reduced or prevented by using the defective light-emitting element as an effective light source, and thus manufacturing cost of the display device can be reduced.

According to the embodiments of the disclosure, because a plurality of sub-electrodes contacting and electrically connected to each end of the light-emitting element are provided, a plurality of current paths may be provided between the light-emitting element and the sub-electrode, and thus reliability of the display device can be improved.

Aspects according to the embodiments are not limited by the contents disclosed above, and more various aspects are included in this specification.

As described above, the optimal embodiments of the present disclosure have been disclosed through the detailed description and the drawings. However, those skilled in the art or those of ordinary skill in the art will appreciate that various modifications and changes are possible without departing from the technical scope of the present disclosure as set forth in the claims below.

Therefore, the technical protection scope of the present disclosure is not limited to the detailed description described in the specification, but should be determined by the appended claims.

What is claimed is:

1. A display device comprising:
a substrate;
a first electrode and a third electrode integrally formed to be electrically connected to each other, and a second electrode and a fourth electrode integrally formed to be electrically connected to each other, the first, second, third, and fourth electrodes being spaced apart from each other above the substrate;
a first dummy electrode and a second dummy electrode spaced apart from each other above the substrate, and electrically insulated from the first, second, third, and fourth electrodes; and
a light-emitting element electrically connected to the first and second electrodes.

2. The display device of claim 1, further comprising:
a pixel circuit layer above the substrate, and comprising a transistor electrically connected to the third electrode; and
a common line above the substrate, and integrally formed with the second and fourth electrodes to be electrically connected to the second and fourth electrodes.

3. The display device of claim 2, wherein the second electrode and the fourth electrode branch from the common line in one direction.

4. The display device of claim 3, wherein the first electrode comprises two or more first sub-electrodes spaced apart from each other, and
wherein the second electrode comprises two or more second sub-electrodes spaced apart from each other.

5. The display device of claim 4, wherein the first sub-electrodes are electrically connected to each other, and the second sub-electrodes are electrically connected to each other.

6. The display device of claim 5, further comprising:
a first connection line above the substrate, and electrically connecting the first sub-electrodes; and
a second connection line above the substrate, and electrically connecting the second sub-electrodes.

7. The display device of claim 4, wherein the first sub-electrodes have widths that are different from that of the third electrode, and
wherein the second sub-electrodes have widths that are different from that of the fourth electrode.

8. The display device of claim 4, wherein the first sub-electrodes have same respective widths, and
wherein the second sub-electrodes have same respective widths.

9. The display device of claim 4, wherein at least one of the first sub-electrodes has a different width than others of the first sub-electrodes, and
wherein at least one of the second sub-electrodes has a different width than others of the second sub-electrodes.

10. The display device of claim 4, wherein the light-emitting element has a horizontal structure comprising a first end and a second end above a same plane, and comprises:
a semiconductor structure comprising a first semiconductor layer, an active layer above the first semiconductor layer, and a second semiconductor layer above the active layer;
a first contact electrode on the semiconductor structure, and at the second end to be electrically connected to the first semiconductor layer; and
a second contact electrode on the semiconductor structure, and at the first end to be electrically connected to the second semiconductor layer.

11. The display device of claim 10, wherein the first semiconductor layer comprises an n-type semiconductor layer doped with an n-type dopant, and
wherein the second semiconductor layer comprises a p-type semiconductor layer doped with a p-type dopant.

12. The display device of claim 11, further comprising:
a first bonding electrode between the first end of the light-emitting element and the first sub-electrodes, and coupling the light-emitting element and the first sub-electrodes; and
a second bonding electrode between the second end of the light-emitting element and the second sub-electrodes, and coupling the light-emitting element and the second sub-electrodes.

13. The display device of claim 1, further comprising:
a cover layer above the light-emitting element;
an optical layer above the cover layer; and
an overcoat layer above the optical layer.

14. A display device comprising:
a substrate;
a first electrode above the substrate, and comprising two or more first sub-electrodes;
a second electrode above the substrate, and comprising two or more second sub-electrodes;
a third electrode spaced apart from the first and second electrodes;
a fourth electrode spaced apart from the first, second, and third electrodes;
a light-emitting element electrically connected to the first electrode and to the second electrode;
a first bridge electrode having one end electrically connected to the second sub-electrodes, and another end electrically connected to the third electrode; and
a second bridge electrode having one end electrically connected to the first sub-electrodes, and another end electrically connected to the fourth electrode.

15. The display device of claim 14, wherein the light-emitting element comprises a second end electrically connected to the first sub-electrodes, and a first end electrically connected to the second sub-electrodes, the first end and the second end being on a same plane, and
wherein a p-type semiconductor layer is at the first end, and an n-type semiconductor layer is at the second end.

16. The display device of claim 15, further comprising:
a pixel circuit layer above the substrate, and comprising a transistor electrically connected to the third electrode; and
a common line above the substrate, and electrically connected to the fourth electrode,
wherein the first sub-electrodes are electrically connected to the fourth electrode and the common line through the second bridge electrode, and
wherein the second sub-electrodes are electrically connected to the third electrode and the transistor through the first bridge electrode.

17. The display device of claim 14, wherein the first sub-electrodes are electrically connected to each other, and
wherein the second sub-electrodes are electrically connected to each other.

18. A repair method of a display device comprising a substrate, a first electrode above the substrate and comprising two or more first sub-electrodes, a second electrode electrically separated from the first electrode above the substrate and comprising two or more second sub-electrodes, a third electrode electrically connected to the first sub-electrodes, a fourth electrode electrically connected to the second sub-electrodes, a first dummy electrode and a second dummy electrode spaced apart from each other above the substrate, and a light-emitting element electrically connected to the first sub-electrodes and the second sub-electrodes, the repair method comprising:
electrically separating the first sub-electrodes and the third electrode from each other using a laser;
electrically separating the second sub-electrodes and the fourth electrode from each other using a laser;
forming a first bridge electrode connecting one end of the first dummy electrode to the second sub-electrodes, and connecting another end of the first dummy electrode to the third electrode through laser welding; and
forming a second bridge electrode connecting one end of the second dummy electrode to the first sub-electrodes, and connecting another end of the second dummy electrode to the fourth electrode through laser welding.

19. The repair method of claim 18, wherein the light-emitting element comprises a second end electrically connected to the first sub-electrodes and the third electrode, and a first end electrically connected to the second sub-electrodes and the fourth electrode,
wherein the second end and the first end are on a same plane,
wherein a p-type semiconductor layer is at the first end, and
wherein an n-type semiconductor layer is at the second end.

20. The repair method of claim 18, wherein the display device further comprises:
a pixel circuit layer above the substrate, and comprising a transistor electrically connected to the third electrode; and
a common line above the substrate, and electrically connected to the fourth electrode,
wherein the first sub-electrodes are electrically connected to the fourth electrode and the common line through the second bridge electrode, and
wherein the second sub-electrodes are electrically connected to the third electrode and the transistor through the first bridge electrode.
